(19) United States
(12) Patent Application Publication
(10) Pub. No.: US 2026/0271419 A1
(43) Pub. Date: Sep. 10, 2026

(54) IMAGING DEVICE AND METHOD OF MANUFACTURING IMAGING DEVICE

(71) Applicant: SONY SEMICONDUCTOR SOLUTIONS CORPORATION, Kanagawa (JP)

(72) Inventors: Shinichiro NOUDO, Kumamoto (JP); Katsuji KIMURA, Kanagawa (JP); Yoshiaki MASUDA, Kanagawa (JP); Keisuke HATANO, Kanagawa (JP); Rikiya HIROSE, Kumamoto (JP)

(73) Assignee: SONY SEMICONDUCTOR SOLUTIONS CORPORATION, Kanagawa (JP)

(21) Appl. No.: 19/167,548

(22) PCT Filed: Mar. 26, 2024
(86) PCT No.: PCT/JP2024/011829

§ 371 Date: Sep. 22, 2025

Related U.S. Application Data
(60) Provisional application No. 63/456,151, filed on Mar. 31, 2023.

(51) Int. Cl. H10F 39/00

(52) U.S. Cl. CPC H10F 39/8063; H10F 39/024; H10F 39/026; H10F 39/811

(57) ABSTRACT

An imaging device includes a solid-state imaging element and a seating. The solid-state imaging element includes, on a base, a light-receiving surface on which a plurality of pixels is arranged in a two-dimensional array. The pixels each include a photoelectric conversion region that converts incident light into an electric signal. The seating is provided with a curved surface recessed in an incident direction of incident light. The seating includes a curved housing section that houses the solid-state imaging element. A back surface of the base opposed to the light-receiving surface and the curved surface are caused to face each other, and the solid-state imaging element is disposed in a curved state on the curved housing section.

### TECHNICAL FIELD

The present disclosure relates to an imaging device and a method of manufacturing the imaging device.

### BACKGROUND ART

PTL 1 discloses an imaging device in which a solid-state imaging element and an imaging lens are combined. In this imaging device, the solid-state imaging element is mounted in a curved shape on a curved seating with an adhesive layer interposed therebetween.

According to the imaging device configured as described above, when an image of a subject is formed by the imaging lens on a light-receiving surface of the solid-state imaging element, it is possible to suppress deviation in focus positions at the center of the light-receiving surface and on a periphery thereof.

In the above-described method of mounting the imaging device, the solid-state imaging element is first placed on the curved seating with the adhesive layer interposed therebetween. Air is released from a side of a back surface of the curved seating to allow the solid-state imaging element to be formed in a curved shape, and the curved shape of the solid-state imaging element is held by the adhesive layer.

Here, when air is released, a protective tape that covers the solid-state imaging element is attached to a side of the light-receiving surface of the solid-state imaging element. The protective tape prevents air leakage, and is detached after the mounting.

### CITATION LIST

### Patent Literature

PTL 1: Japanese Unexamined Patent Application Publication No. 2015-70159

### SUMMARY OF THE INVENTION

In an imaging device, a protective tape that covers a light-receiving surface of a solid-state imaging element is used upon mounting. Concerning the present disclosure, it has been desired to develop an imaging device in which a protective tape is not brought into contact with a light-receiving surface of a solid-state imaging element as well as a method of manufacturing the imaging device.

An imaging device according to a first embodiment of the present disclosure includes a solid-state imaging element and a seating. The solid-state imaging element includes, on a base, a light-receiving surface on which a plurality of pixels is arranged in a two-dimensional array. The pixels each include a photoelectric conversion region that converts incident light into an electric signal. The seating is provided with a curved surface recessed in an incident direction of incident light. The seating includes a curved housing section that houses the solid-state imaging element. In this imaging device, the light-receiving surface and the curved surface are caused to face each other, and the solid-state imaging element is disposed in a curved state on the curved housing section.

In an imaging device according to a second embodiment of the present disclosure, a film is disposed between the solid-state imaging element and the curved housing section, in the imaging device according to the first embodiment.

An imaging device according to a third embodiment of the present disclosure includes a mounting substrate to be mounted with the seating on a side of a back surface opposed to the curved surface, in the imaging device according to the first embodiment, and the seating includes an electric conductor having one end being electrically coupled to the solid-state imaging element in the curved housing section, and another end being electrically coupled to the mounting substrate.

An imaging device according to a fourth embodiment of the present disclosure further includes, between the solid-state imaging element and the curved housing section of the seating, a wiring substrate including a wiring layer and being formed in a curved shape along the curved surface of the curved housing section, in the imaging device according to the first embodiment.

A method of manufacturing an imaging device according to a fifth embodiment of the present disclosure includes: forming a solid-state imaging element including, on a base, a light-receiving surface on which a plurality of pixels is arranged in a two-dimensional array, the pixels each including a photoelectric conversion region that converts incident light into an electric signal; forming a seating provided with a curved surface recessed in an incident direction of incident light, the seating including a curved housing section that houses the solid-state imaging element; causing the light-receiving surface and the curved surface to face each other; and forming the solid-state imaging element in a curved state on the curved housing section, with a film being interposed between the solid-state imaging element and the curved housing section.

### BRIEF DESCRIPTION OF THE DRAWINGS

FIG. 1A is a planar configuration diagram in a first step describing a first manufacturing method (mounting method) of an imaging device according to a first embodiment of the present disclosure.

FIG. 1B is a cross-sectional configuration diagram in the first step illustrated in FIG. 1A.

FIG. 2A is a planar configuration diagram in a second step.

FIG. 2B is a cross-sectional configuration diagram in the second step illustrated in FIG. 2A.

FIG. 3A is a planar configuration diagram in a third step.

FIG. 3B is a cross-sectional configuration diagram in the third step illustrated in FIG. 3A.

FIG. 4A is a planar configuration diagram in a fourth step.

FIG. 4B is a cross-sectional configuration diagram in the fourth step illustrated in FIG. 4A.

FIG. 5 is a cross-sectional configuration diagram of a modification example of the third step.

FIG. 6 is a cross-sectional configuration diagram in a fifth step.

FIG. 7 is a cross-sectional configuration diagram in a sixth step.

FIG. 8 is a cross-sectional configuration diagram in a seventh step.

FIG. 9 is a cross-sectional configuration diagram of a modification example of the fourth step.

FIG. 10 is a step diagram illustrating a first modification example of the first manufacturing method in a case where a portion of the solid-state imaging element extends to the outside from a curved housing section of a seating. (A) of FIG. 10 is a planar configuration diagram of the seating before mounting. (B) of FIG. 10 is a cross-sectional configuration diagram of the seating before the mounting. (C) of FIG. 10 is a planar configuration diagram of the solid-state imaging element before the mounting. (D) of FIG. 10 is a planar configuration diagram of an imaging device mounted with the solid-state imaging element on the curved housing section of the seating. (E) of FIG. 10 is a cross-sectional configuration diagram of the imaging device taken along a line E-E illustrated in (D) of FIG. 10. (F) of FIG. 10 is a cross-sectional configuration diagram of the imaging device taken along a line F-F illustrated in (D) of FIG. 10.

FIG. 11 is a step diagram illustrating a second modification example of the first manufacturing method in a case where the solid-state imaging element is completely contained in the curved housing section of the seating. (A) of FIG. 11 is a planar configuration diagram of the seating before mounting. (B) of FIG. 11 is a cross-sectional configuration diagram of the seating before the mounting. (C) of FIG. 11 is a planar configuration diagram of the solid-state imaging element before the mounting. (D) of FIG. 11 is a planar configuration diagram of an imaging device mounted with the solid-state imaging element on the curved housing section of the seating. (E) of FIG. 11 is a cross-sectional configuration diagram of the imaging device taken along a line E-E illustrated in (D) of FIG. 11. (F) of FIG. 11 is a cross-sectional configuration diagram of the imaging device taken along a line F-F illustrated in (D) of FIG. 11.

FIG. 12 is a step diagram illustrating a third modification example of the first manufacturing method in which the solid-state imaging element is mounted on the curved housing section of the seating. (A) of FIG. 12 is a planar configuration diagram of the seating before mounting. (B) of FIG. 12 is a cross-sectional configuration diagram of the seating before the mounting. (C) of FIG. 12 is a cross-sectional configuration diagram of an imaging device in which the solid-state imaging element is mounted on the curved housing section of the seating by utilizing a pressure difference due to depressurization. (D) of FIG. 12 is a cross-sectional configuration diagram of an imaging device in which the solid-state imaging element is mounted on the curved housing section of the seating by utilizing a pressure difference due to pressurization.

FIG. 13 is a diagram describing a first configuration according to a modification example of the seating. (A) of FIG. 13 is a planar configuration diagram of the seating before mounting. (B) of FIG. 13 is a cross-sectional configuration diagram of the seating before the mounting.

FIG. 14 is a step diagram illustrating a fourth modification example of the first manufacturing method in which the solid-state imaging element is mounted on the curved housing section of the seating. (A) of FIG. 14 is a planar configuration diagram of the seating before mounting. (B) of FIG. 14 is a cross-sectional configuration diagram of the seating before the mounting. (C) of FIG. 14 is a cross-sectional configuration diagram at the time when the solid-state imaging element is placed on the curved housing section of the seating. (D) of FIG. 14 is a cross-sectional configuration diagram of an imaging device in which the solid-state imaging element is mounted on the curved housing section of the seating.

FIG. 15A is a planar configuration diagram of the seating describing a variation of a position at which a pocket is disposed.

FIG. 15B is a cross-sectional configuration diagram of the seating illustrated in FIG. 15A.

FIG. 15C is a planar configuration diagram of the seating describing a variation of a position at which the pocket is disposed.

FIG. 15D is a cross-sectional configuration diagram of the seating illustrated in FIG. 15C.

FIG. 15E is a planar configuration diagram of the seating describing a variation of a position at which the pocket is disposed.

FIG. 15F is a cross-sectional configuration diagram of the seating illustrated in FIG. 15E.

FIG. 16 is a diagram describing a second configuration according to a modification example of the seating. (A) of FIG. 16 is a cross-sectional configuration diagram of the seating and the solid-state imaging element before mounting. (B) of FIG. 16 is an enlarged cross-sectional configuration diagram of a main part of the seating and the solid-state imaging element.

FIG. 17 is a planar configuration diagram describing a third configuration according to a modification example of the seating.

FIG. 18 is a cross-sectional configuration diagram of an imaging device according to a second embodiment of the present disclosure.

FIG. 19 is a cross-sectional configuration diagram of an imaging device according to a modification example of the second embodiment.

FIG. 20A is a cross-sectional view of a first step describing a first manufacturing method of the imaging device according to the second embodiment.

FIG. 20B is a cross-sectional view of a second step.

FIG. 20C is a cross-sectional view of a third step.

FIG. 20D is a cross-sectional view of a fourth step.

FIG. 20E is a cross-sectional view of a fifth step.

FIG. 20F is a cross-sectional view of a sixth step.

FIG. 20G is a cross-sectional view of a seventh step.

FIG. 20H is a cross-sectional view of an eighth step.

FIG. 21A is a cross-sectional view of a first step describing a second manufacturing method of the imaging device according to the second embodiment.

FIG. 21B is a cross-sectional view of a second step.

FIG. 21C is a cross-sectional view of a third step.

FIG. 21D is a cross-sectional view of a fourth step.

FIG. 21E is a cross-sectional view of a fifth step.

FIG. 21F is a cross-sectional view of a sixth step.

FIG. 21G is a cross-sectional view of a seventh step.

FIG. 22 is a cross-sectional configuration diagram of an imaging device according to a third embodiment of the present disclosure.

FIG. 23 is a cross-sectional configuration diagram of an imaging device according to a modification example of the third embodiment.

FIG. 24A is a planar configuration diagram of the seating in a first step describing a first manufacturing method of the imaging device according to the third embodiment.

FIG. 24B is a cross-sectional configuration diagram of the seating illustrated in FIG. 24A.

FIG. 25A is a planar configuration diagram of the seating in a second step.

FIG. 25B is a cross-sectional configuration diagram of the seating illustrated in FIG. 25A.

FIG. 26A is a planar configuration diagram of a solid-state imaging element and the seating in a third step.

FIG. 26B is a cross-sectional configuration diagram of the solid-state imaging element and the seating illustrated in FIG. 26A.

FIG. 27A is a planar configuration diagram of the solid-state imaging element and the seating in a fourth step.

FIG. 27B is a cross-sectional configuration diagram of the solid-state imaging element and the seating illustrated in FIG. 27A.

FIG. 28 is a cross-sectional configuration diagram of the solid-state imaging element and the seating in a modification example of the fourth step.

FIG. 29 is a cross-sectional configuration diagram of the solid-state imaging element and the seating in a fifth step.

FIG. 30 is a cross-sectional configuration diagram of the solid-state imaging element and the seating in a sixth step. FIG. 31 is a cross-sectional configuration diagram of the solid-state imaging element, the seating, and a mounting substrate in a seventh step.

FIG. 32 is a cross-sectional configuration diagram of the solid-state imaging element, the seating, and the mounting substrate in an eighth step.

FIG. 33A is a planar configuration diagram of the seating in a first step describing a second manufacturing method of the imaging device according to the third embodiment.

FIG. 33B is a cross-sectional configuration diagram of the seating illustrated in FIG. 33A.

FIG. 34A is a planar configuration diagram of the seating in a second step.

FIG. 34B is a cross-sectional configuration diagram of the seating illustrated in FIG. 34A.

FIG. 35A is a planar configuration diagram of the solid-state imaging element and the seating in a third step.

FIG. 35B is a cross-sectional configuration diagram of the solid-state imaging element and the seating illustrated in FIG. 35A.

FIG. 36A is a planar configuration diagram of the solid-state imaging element and the seating in a fourth step.

FIG. 36B is a cross-sectional configuration diagram of the solid-state imaging element and the seating illustrated in FIG. 36A.

FIG. 37 is a cross-sectional configuration diagram of the solid-state imaging element and the seating in a modification example of the fourth step.

FIG. 38 is a cross-sectional configuration diagram of the solid-state imaging element and the seating in a fifth step.

FIG. 39 is a cross-sectional configuration diagram of the solid-state imaging element, the seating, and the mounting substrate in a sixth step.

FIG. 40 is a cross-sectional configuration diagram of the solid-state imaging element, the seating, and the mounting substrate in a seventh step.

FIG. 41A is a planar configuration diagram of the seating in a first step describing a third manufacturing method of the imaging device according to the third embodiment.

FIG. 41B is a cross-sectional configuration diagram of the seating illustrated in FIG. 41A.

FIG. 42A is a planar configuration diagram of the solid-state imaging element and the seating in a second step.

FIG. 42B is a cross-sectional configuration diagram of the solid-state imaging element and the seating illustrated in FIG. 42A.

FIG. 43A is a planar configuration diagram of the solid-state imaging element and the seating in a third step.

FIG. 43B is a cross-sectional configuration diagram of the solid-state imaging element and the seating illustrated in FIG. 43A.

FIG. 44A is a planar configuration diagram of the solid-state imaging element and the seating in a fourth step.

FIG. 44B is a cross-sectional configuration diagram of the solid-state imaging element and the seating illustrated in FIG. 44A.

FIG. 45 is a cross-sectional configuration diagram of the solid-state imaging element and the seating in a modification example of the fourth step.

FIG. 46 is a cross-sectional configuration diagram of the solid-state imaging element and the seating in a fifth step.

FIG. 47 is a cross-sectional configuration diagram of the solid-state imaging element, the seating, and the mounting substrate in a sixth step.

FIG. 48 is a cross-sectional configuration diagram of the solid-state imaging element, the seating, and the mounting substrate in a seventh step.

FIG. 49 is a cross-sectional configuration diagram of the imaging device in an eighth step.

FIG. 50A is a planar configuration diagram of the seating in a first step describing a fourth manufacturing method of the imaging device according to the third embodiment.

FIG. 50B is a cross-sectional configuration diagram of the seating illustrated in FIG. 50A.

FIG. 51A is a planar configuration diagram of a film and the seating in a second step.

FIG. 51B is a cross-sectional configuration diagram of the film and the seating illustrated in FIG. 51A.

FIG. 52A is a planar configuration diagram of the film, the solid-state imaging element, and the seating in a third step.

FIG. 52B is a cross-sectional configuration diagram of the film, the solid-state imaging element, and the seating illustrated in FIG. 52A.

FIG. 53A is a planar configuration diagram of the film, the solid-state imaging element, and the seating in a fourth step.

FIG. 53B is a cross-sectional configuration diagram of the film, the solid-state imaging element, and the seating illustrated in FIG. 53A.

FIG. 54 is a cross-sectional configuration diagram of the film, the solid-state imaging element, and the seating in a modification example of the fourth step.

FIG. 55 is a cross-sectional configuration diagram of the film, the solid-state imaging element, the seating, and the mounting substrate in a fifth step.

FIG. 56 is a cross-sectional configuration diagram of the film, the solid-state imaging element, the seating, and the mounting substrate in a sixth step.

FIG. 57 is a cross-sectional configuration diagram of the imaging device in a seventh step.

FIG. 58A is a planar configuration diagram describing a first configuration of the seating of the imaging device according to the third embodiment.

FIG. 58B is a cross-sectional configuration diagram of the seating illustrated in FIG. 58A.

FIG. 59A is a planar configuration diagram describing a second configuration of the seating of the imaging device according to the third embodiment.

FIG. 59B is a cross-sectional configuration diagram of the seating illustrated in FIG. 59A.

FIG. 60 is a step diagram illustrating a manufacturing method in which the solid-state imaging element is mounted on the curved housing section of the seating. (A) of FIG. 60 is a planar configuration diagram describing a third configuration of the seating before mounting. (B) of FIG. 60 is a cross-sectional configuration diagram of the seating before the mounting. (C) of FIG. 60 is a cross-sectional configuration diagram at the time when the solid-state imaging element is placed on the curved housing section of the seating. (D) of FIG. 60 is a cross-sectional configuration diagram of the imaging device in which the solid-state imaging element is mounted on the curved housing section of the seating.

FIG. 61 is a diagram describing a fourth configuration of the seating. (A) of FIG. 61 is a cross-sectional configuration diagram of the seating and the solid-state imaging element before mounting. (B) of FIG. 61 is an enlarged cross-sectional configuration diagram of a main part of the seating and the solid-state imaging element.

FIG. 62 is a planar configuration diagram describing a fifth configuration of the seating.

FIG. 63A is a cross-sectional configuration diagram of the solid-state imaging element describing a first coupling configuration of the imaging device.

FIG. 63B is a planar configuration diagram of the seating describing the first coupling configuration.

FIG. 63C is a cross-sectional configuration diagram of the seating describing the first coupling configuration.

FIG. 63D is a cross-sectional configuration diagram of the mounting substrate describing the first coupling configuration.

FIG. 64A is a cross-sectional configuration diagram of the solid-state imaging element describing a second coupling configuration of the imaging device.

FIG. 64B is a planar configuration diagram of the seating describing the second coupling configuration.

FIG. 64C is a cross-sectional configuration diagram of the seating describing the second coupling configuration.

FIG. 65A is a cross-sectional configuration diagram of the solid-state imaging element describing a third coupling configuration of the imaging device.

FIG. 65B is a planar configuration diagram of the seating describing the third coupling configuration.

FIG. 65C is a cross-sectional configuration diagram of the seating describing the third coupling configuration.

FIG. 65D is a cross-sectional configuration diagram of the mounting substrate describing the third coupling configuration.

FIG. 66A is a cross-sectional configuration diagram of the solid-state imaging element describing a fourth coupling configuration of the imaging device.

FIG. 66B is a planar configuration diagram of the seating describing the fourth coupling configuration.

FIG. 66C is a cross-sectional configuration diagram of the seating describing the fourth coupling configuration.

FIG. 67A is a cross-sectional configuration diagram of the solid-state imaging element describing a fifth coupling configuration of the imaging device.

FIG. 67B is a planar configuration diagram of the seating describing the fifth coupling configuration.

FIG. 67C is a cross-sectional configuration diagram of the seating describing the fifth coupling configuration.

FIG. 67D is a cross-sectional configuration diagram of the mounting substrate describing the fifth coupling configuration.

FIG. 68A is a cross-sectional configuration diagram of the solid-state imaging element describing a sixth coupling configuration of the imaging device.

FIG. 68B is a planar configuration diagram of the seating describing the sixth coupling configuration.

FIG. 68C is a cross-sectional configuration diagram of the seating describing the sixth coupling configuration.

FIG. 69 is a cross-sectional configuration diagram of an imaging device according to a fourth embodiment of the present disclosure.

FIG. 70 is a cross-sectional configuration diagram of an imaging device according to a modification example of the fourth embodiment.

FIG. 71 is a cross-sectional configuration diagram of an imaging device according to a fifth embodiment of the present disclosure.

FIG. 72 is a cross-sectional configuration diagram of an imaging device according to a modification example of the fifth embodiment.

### MODES FOR CARRYING OUT THE INVENTION

Hereinafter, description is given in detail of embodiments of the present disclosure with reference to the drawings. It is to be noted that the description is given in the following order.

### 1. First Embodiment

A first embodiment describes an example in which the present technology is applied to an imaging device and a method of manufacturing of the imaging device. The first embodiment describes a specific configuration of the imaging device and a specific method of manufacturing the imaging device.

### 2. Second Embodiment

A second embodiment describes an imaging device including an element section and an optical section, and a method of manufacturing the imaging device. Further, the second embodiment describes the imaging device provided with a wiring substrate in the element section, and a method of manufacturing the imaging device.

### 3. Third Embodiment

A third embodiment describes an imaging device further including a mounting substrate mounted with a seating and a method of manufacturing the imaging device, in the imaging device and the method of manufacturing the imaging device according to the second embodiment.

### 4. Fourth Embodiment

A fourth embodiment describes an imaging device further including an intermediate wiring substrate and a method of manufacturing the imaging device, in the imaging device and the method of manufacturing the imaging device according to the third embodiment.

5. Fifth Embodiment A fifth embodiment describes an imaging device further including a logic chip and a method of manufacturing the imaging device, in the imaging device and the method of manufacturing the imaging device according to the third embodiment.

### 6. Other Embodiments

### <1. First Embodiment>

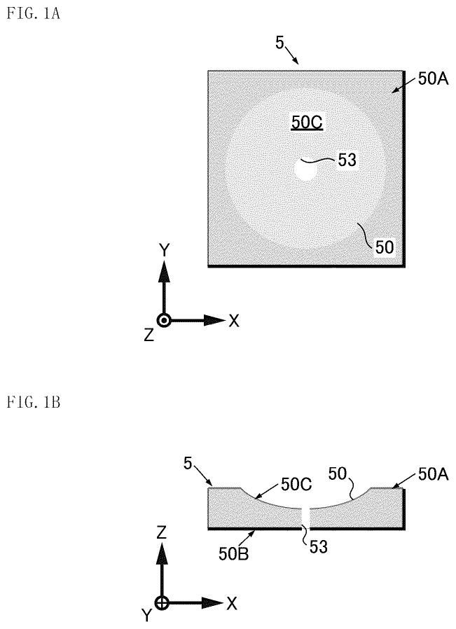

Description is given, with reference to FIGS. 1 to 17, of an imaging device 1 and a method of manufacturing the imaging device 1 according to the first embodiment of the present disclosure.

Here, an arrow-X direction indicated as appropriate in the drawings indicates one planar direction of the imaging device 1 placed on a plane for convenience. An arrow-Y direction indicates another planar direction orthogonal to the arrow-X direction. In addition, an arrow-Z direction indicates an upward direction orthogonal to the arrow-X direction and the arrow-Y direction. That is, the arrow-X direction, the arrow-Y direction, and the arrow-Z direction exactly coincide with an X-axis direction, a Y-axis direction, and a Z-axis direction, respectively, of a three-dimensional coordinate system.

It is to be noted that these directions are each indicated to aid understanding of descriptions, and are not intended to limit directions used in the present technology.

In addition, in the first embodiment and other embodiments described later, components the same or substantially the same as one another are denoted by the same reference numerals, and redundant descriptions are omitted.

### [Configuration of Imaging Device 1 and First Manufacturing Method of Imaging Device 1]

A first manufacturing method (mounting method) of the imaging device 1 according to the first embodiment is as follows.

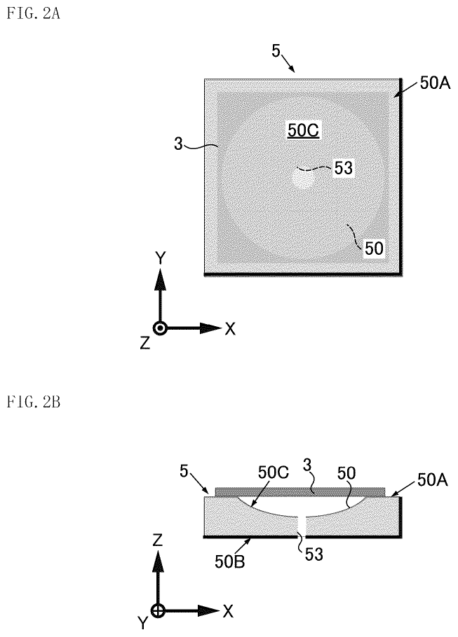

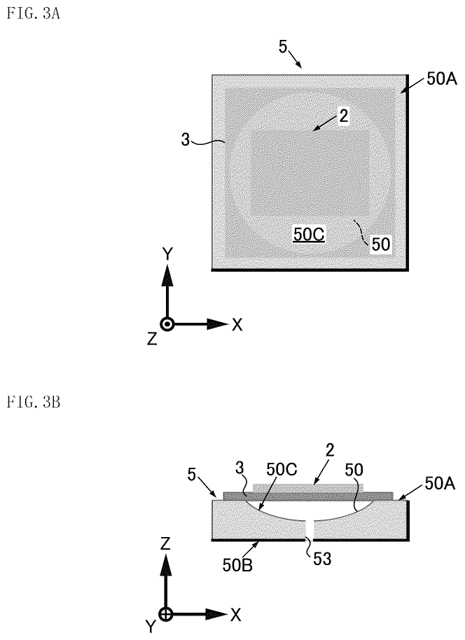

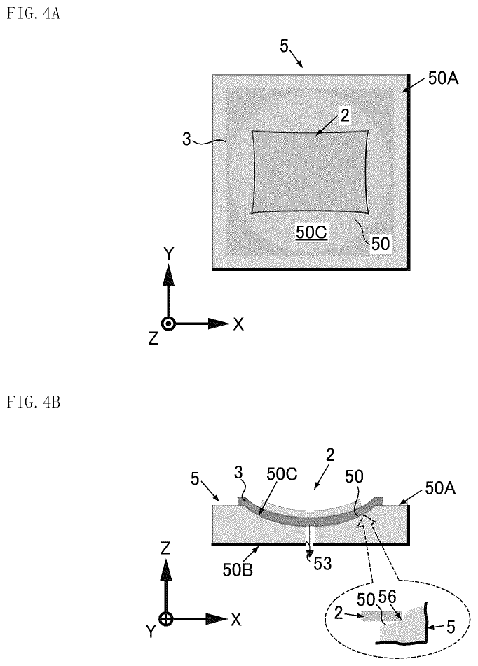

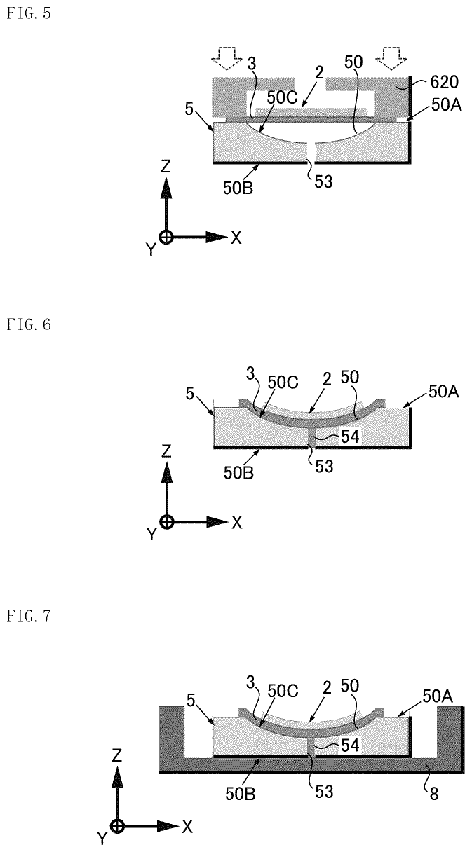

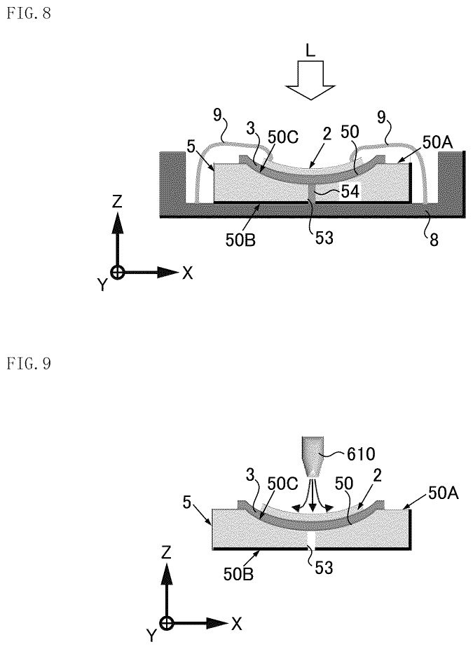

Here, FIG. 1A illustrates a planar configuration in a first step describing a manufacturing method of the imaging device 1. FIG. 1B illustrates an example of a cross-sectional configuration in the first step illustrated in FIG. 1A. FIG. 2A illustrates an example of a planar configuration in a second step. FIG. 2B illustrates an example of a cross-sectional configuration in the second step illustrated in FIG. 2A. FIG. 3A illustrates an example of a planar configuration in a third step. FIG. 3B illustrates an example of a cross-sectional configuration in the third step illustrated in FIG. 3A. FIG. 4A illustrates an example of a planar configuration in a fourth step. FIG. 4B illustrates an example of a cross-sectional configuration in the fourth step illustrated in FIG. 4A. FIG. 5 illustrates an example of a cross-sectional configuration according to a modification example of the third step. FIG. 6 illustrates an example of a cross-sectional configuration in a fifth step. FIG. 7 illustrates an example of a cross-sectional configuration in a sixth step. FIG. 8 illustrates an example of a cross-sectional configuration in a seventh step. FIG. 9 illustrates an example of a cross-sectional configuration according to a modification example of the fourth step.

The imaging device 1 according to the first embodiment includes a solid-state imaging element 2 and a seating 5 (see FIG. 8).

The solid-state imaging element 2 includes, on a base, a light-receiving surface 2A on which a plurality of pixels, each of which includes a photoelectric conversion region, is arranged in a two-dimensional array. The photoelectric conversion region converts incident light L into an electric signal. The base is configured, for example, by stacking a single-crystal silicon substrate and a wiring layer, although detailed illustration is omitted.

The seating 5 is provided with a curved surface 50C that is recessed in an incident direction of incident light, and includes a curved housing section 50 that houses the solid-state imaging element 2.

In the imaging device 1, a back surface 2B of the base opposed to the light-receiving surface 2A faces the curved surface 50C, and the solid-state imaging element 2 is disposed in a curved state on the curved housing section 50.

First, the seating 5 is prepared as illustrated in FIGS. 1A and 1B. The seating 5 includes the curved housing section 50 at a middle part of a front surface 50A. The curved housing section 50 is recessed from the front surface 50A in the incident direction of the incident light L, and is formed in a curved shape in a side view. The curved housing section 50 of the seating 5 may be formed in a curved shape in which a normal line of the curved surface 50C coincides with respect to a principal light beam axis angle (CRA: Chief Ray Angle) of a module lens.

The seating 5 includes, in the curved housing section 50, a ventilation section 53 penetrating from the curved surface 50C to a side of a back surface 50B opposed to the curved surface 50C. The ventilation section 53 is able to discharge a gas to the outside of the seating 5 from the inside of space closed by the solid-state imaging element 2, a film 3 (see FIGS. 3A and 3B), and the curved housing section 50 of the seating 5, when the solid-state imaging element 2 is curved by a pressure difference between gases such as air.

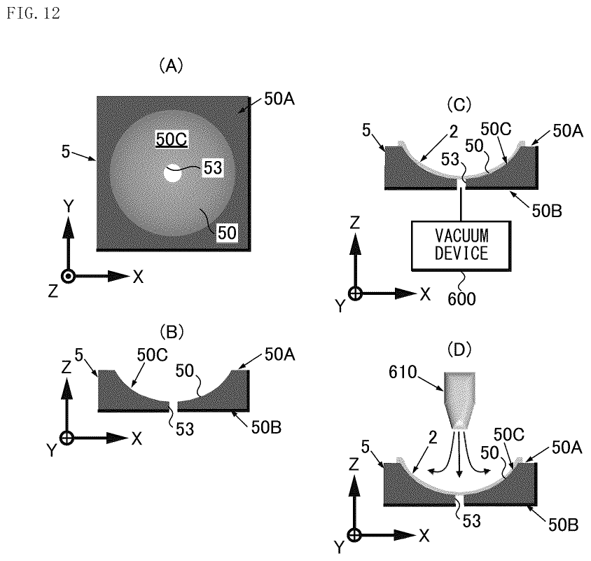

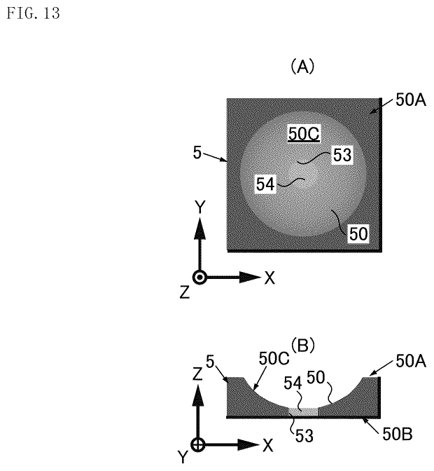

The ventilation section 53 is formed by a through-hole. An embedded member 54 (see (A) and (B) of FIG. 13) such as a porous (porous) material described later may be embedded in the ventilation section 53.

As illustrated in FIGS. 2A and 2B, the film 3 is attached to the front surface 50A to cover the curved housing section 50 of the seating 5. The film 3 is attached to seal the curved housing section 50.

The film 3 is formed, for example, by an organic material, and is softer than the solid-state imaging element 2. In addition, a glue is applied to a front surface and a back surface of the film 3. As the glue, for example, a resin glue is used.

Here, as the glue, for example, one or more resin glues selected from an epoxy-based resin, an acrylic-based resin, and a cyan-based resin are used. As the glue, an ultraviolet ray (UV)-cured type, a temperature-cured type, a time-cured type, or the like is usable, and no particular limitation is made on the cured type.

In a case where the UV-cured type is adopted as the glue, the seating 5 is formed by a material that transmits UV.

As illustrated in FIGS. 3A and 3B, the solid-state imaging element 2 is attached to the seating 5 with the film 3 interposed therebetween, at a position corresponding to the curved housing section 50. The glue is applied in advance to the film 3, and thus the solid-state imaging element 2 is adhered to the surface of the film 3.

Here, when a deviation occurs at a mounting position of the solid-state imaging element 2 with respect to the curved housing section 50 of the seating 5, a deviation occurs in optical axes between the solid-state imaging element 2 and the module lens, thus causing image quality to be degraded.

Therefore, the film 3 or the seating 5 is provided with a mark 57 (or a marker, see FIG. 17) for positioning, and the solid-state imaging element 2 is disposed at an accurate position using an optical alignment mechanism and a finely adjustable pick-up arm.

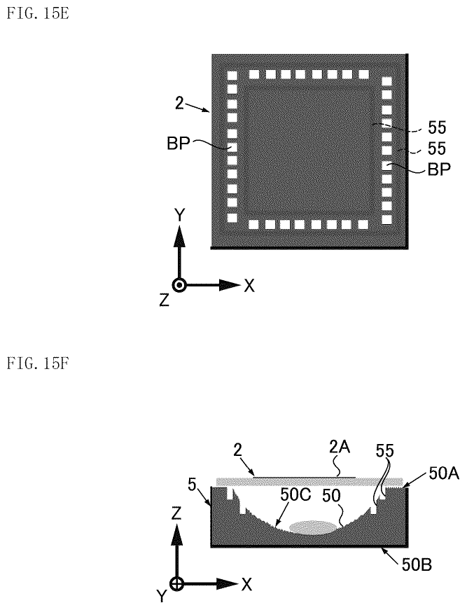

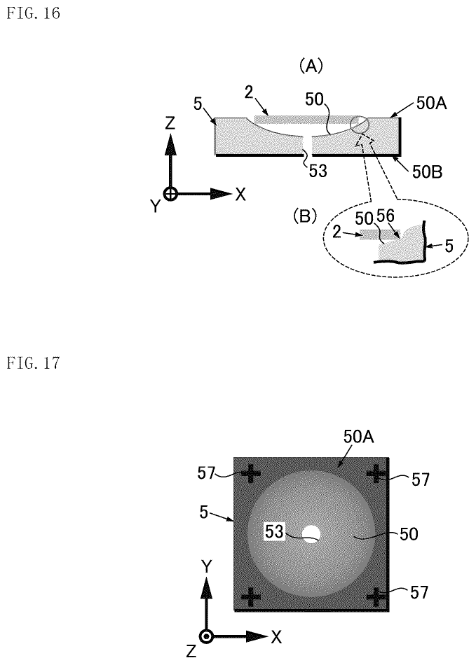

In addition, a stepped part 56 (see FIG. 16) serving as a guide to position the solid-state imaging element 2 may be formed on the curved surface 50C of the curved housing section 50 of the seating 5.

Further, as illustrated in FIG. 5, a collet 620 may be prepared, and the film 3 may be pressed against the front surface 50A of the seating 5 using the collet 62. In this case, it is possible to effectively suppress or prevent positioning misalignment due to insufficient adhesive force of the glue of the film 3.

As illustrated in FIGS. 4A and 4B, a gas inside the curved housing section 50 is released from the ventilation section 53 of the seating 5, and the inside of the curved housing section 50 has a negative pressure. This causes the film 3 and the solid-state imaging element 2 to be sucked to the curved surface 50C of the curved housing section 50, and the film 3 and the solid-state imaging element 2 are formed, in the curved housing section 50, in a curved shape along a shape of the curved surface 50C. That is, the film 3 and the solid-state imaging element 2 are formed in a curved shape that is recessed in the incident direction of the incident light L (a direction opposite to the arrow-Z direction).

When the glue is cured, the solid-state imaging element 2 formed in the curved shape is then fastened to the curved housing section 50 of the seating 5 with the film 3 interposed therebetween, because the glue is formed on the back surface of the film 3. In other words, the solid-state imaging element 2 is mounted on the curved housing section 50 of the seating 5.

As illustrated in FIG. 6, the embedded member 54 is embedded in the ventilation section 53 of the seating 5. When the ventilation section 53 is clogged with the embedded member 54, it is possible to effectively suppress or prevent a phenomenon in which the incident light L of a long wavelength passes through the thinned solid-state imaging element 2 and is reflected by the seating 5 to cause a shape of the curved housing section 50 to be reflected therein.

In addition, the clogging of the ventilation section 53 makes it possible to effectively suppress or prevent loss of a stress balance, near the ventilation section 53, of the base of the solid-state imaging element 2 mounted on the curved housing section 50 of the seating 5. It is therefore possible, in the solid-state imaging element 2, to effectively suppress or prevent deterioration of a dark current and a white spot.

Further, when the embedded member 54 is formed by a material having high thermal conductivity, it is possible to improve a heat dissipation effect.

From such a viewpoint, as the embedded member 54, one or more materials are used, which are selected from among a material having a reflectance close to that of the seating 5, a material that is able to fill the entire region of the ventilation section 53 without generation of a void, and a material having high thermal conductivity.

For example, a mask is used to enable the embedded member 54 to be selectively pasted in the ventilation section 53. At this time, it may be possible to use, as the embedded member 54, a high-melting-point material including tin (Sn), silver (Ag), copper (Cu), lead (Pb), or the like.

In addition, the embedded member 54 may be formed in advance in a wiring substrate 7 (see FIG. 17) described later. As the wiring substrate, for example, a flexible printed circuit (FPC: Flexible Printed Circuits) substrate having flexibility is used, in the present technology. The wiring substrate 7 is disposed between the seating 5 and the solid-state imaging element 2. Accordingly, the embedded member 54 is embedded in advance in the wiring substrate 7 at a position corresponding to the ventilation section 53. It may be possible to practically use, as the embedded member 54, Cu formed on a metal such as wiring of the wiring substrate 7. Cu is formed by plating processing, for example.

Further, it may be possible to use, as the embedded member 54, an electrically-conductive resin used for an underfill (under fill) material or the like.

As illustrated in FIG. 7, the seating 5 is fixed to a package 8.

Subsequently, a wire 9 is formed as illustrated in FIG. 8. One end of the wire 9 is electrically coupled to a terminal (bonding pad) of the unillustrated solid-state imaging element 2, and the other end thereof is electrically coupled to a terminal of the unillustrated package 8. For example, a gold (Au) wire is used as the wire 9. In addition, the wire 9 is coupled using an ultrasonic vibration method or a thermocompression bonding method.

When the series of steps is finished, the imaging device 1 in which the solid-state imaging element 2 is mounted on the curved housing section 50 of the seating 5 is completed.

It is to be noted that the present disclosure is not limited to the first manufacturing method of the imaging device 1 described above.

For example, the glue may be applied to the solid-state imaging element 2 instead of the film 3.

In addition, as the film 3, a die attach film (DAF: Die Attach Film) may be used. In this case, the film 3 may be used to form the solid-state imaging element 2 from a semiconductor wafer by dicing, and the used film 3 may be used to attach the solid-state imaging element 2 to the seating 5 by dicing.

In addition, the glue may be applied to the curved surface 50C of the curved housing section 50 of the seating 5. In this case, no glue is applied to a side of the back surface of the film 3.

In addition, in the first manufacturing method of the imaging device 1, the film 3 is first attached to the seating 5; however, the solid-state imaging element 2 may be first attached to the film 3, and then the film 3 and the solid-state imaging element 2 may be placed on the seating 5.

Further, as illustrated in FIG. 9, in the first manufacturing method of the imaging device 1 described above, for example, a gas such as air may be blown from a nozzle 610 to release the gas in the sealed space between the film 3 and the curved housing section 50 from the ventilation section 53 while pressurizing the entirety of the film 3 and the solid-state imaging element 2. The blowing of the gas enables the solid-state imaging element 2 and the film 3 to be easily formed in a curved shape along the curved surface 50C of the curved housing section 50 of the seating 5.

### [Workings and Effects]

The imaging device 1 according to the first embodiment includes the solid-state imaging element 2 and the seating 5, as illustrated in FIGS. 4A and 4B and 8.

The solid-state imaging element 2 includes, on the base, the light-receiving surface 2A on which a plurality of pixels, each of which includes a photoelectric conversion region, is arranged in a two-dimensional array. The photoelectric conversion region converts the incident light L into an electric signal. The seating 5 is provided with the curved surface 50C that is recessed in the incident direction of the incident light L, and includes the curved housing section that houses the solid-state imaging element. The back surface of the base opposed to the light-receiving surface 2A then faces the curved surface 50C, and the solid-state imaging element 2 is disposed in a curved state on the curved housing section 50.

To be described in detail, the film 3 is disposed between the solid-state imaging element 2 and the curved housing section 50 of the seating 5. The film 3 is softer than the solid-state imaging element 2. The glue is formed on the surface of the film 3 on a side of the solid-state imaging element 2 and on the surface thereof on a side of the curved surface 50C.

According to the imaging device 1 configured as described above, the film 3 is not disposed on the light-receiving surface 2A of the solid-state imaging element 2, and thus the light-receiving surface 2A of the solid-state imaging element 2 and the film 3 are not brought into contact with each other. For example, it is possible to effectively suppress or prevent damage of the light-receiving surface 2A of the solid-state imaging element 2.

In addition, in the first manufacturing method of the imaging device 1, the solid-state imaging element 2 is first formed which includes, on the base, the light-receiving surface 2A on which a plurality of pixels, each of which includes a photoelectric conversion region, is arranged in a two-dimensional array. The photoelectric conversion region converts the incident light L into an electric signal. Next, the curved surface 50C that is recessed in the incident direction of the incident light L is provided, and the seating 5 including the curved housing section 50 that houses the solid-state imaging element 2 is formed. The back surface of the base opposed to the light-receiving surface 2A is then allowed to face the curved surface 50C, and the solid-state imaging element 2 is formed in a curved state on the curved housing section 50 with the film 3 interposed between the solid-state imaging element 2 and the curved housing section 50.

According to the first manufacturing method of the imaging device 1 configured as described above, it is possible to mount the solid-state imaging element 2 having a curved shape on the seating 5 without bringing the light-receiving surface 2A of the solid-state imaging element 2 and the film 3 into contact with each other.

### [Modification Example of Configuration of Imaging Device 1 and First Manufacturing Method of Imaging Device 1]

As illustrated in FIG. 8 mentioned above, the imaging device 1 includes the seating 5 including the curved housing section 50. The curved surface 50C of the curved housing section 50 is formed along an image-forming surface of an unillustrated module lens.

According to the imaging device 1 configured as described above, it is possible to reduce a corresponding load of image plane distortion in designing the module lens. In addition, it is possible to achieve a reduction in the number of lenses of the module lens, a reduction in the height of the module lens, higher resolution of the module lens, and the like.

In addition, the curved housing section 50 of the seating 5 may be formed in a curved shape in which the normal line of the curved surface 50C coincides with respect to the CRA of the module lens.

In addition, according to the seating 5 having such a shape, even in the case of high image height, a principal light beam is incident on the solid-state imaging element 2 vertically, thus making it possible to effectively suppress sensitivity loss due to vignetting (celare: vignetting) in a pixel of the solid-state imaging element 2 and degradation in image quality such as oblique light color mixture.

Further, the imaging device 1 may be provided with an infrared-absorbing filter formed in a curved shape in the same manner, on a side of the light-receiving surface 2A of the solid-state imaging element 2 fixed in a curved shape to the curved housing section 50 of the seating 5. This eliminates dependence on image height for an optical path difference in the infrared-absorbing filter, thus making it possible to effectively suppress or prevent color shading.

In the imaging device 1, the solid-state imaging element 2 needs to be fixed to the curved housing section 50 of the seating 5 without causing a crack. In accordance with the physical principle, a thinner Si substrate that forms the base of the solid-state imaging element 2 is curved more easily. However, when handling the solid-state imaging element 2 as a sample, the possibility of the solid-state imaging element 2 being cracked is high.

For this reason, in reality, the thickness of the Si substrate is set to a range of 10 μm or more and 50 μm or less. Further, the thickness of the Si substrate is preferably set to a range of 15 μm or more and 35 μm or less.

### (1) First Modification Example of First Manufacturing Method

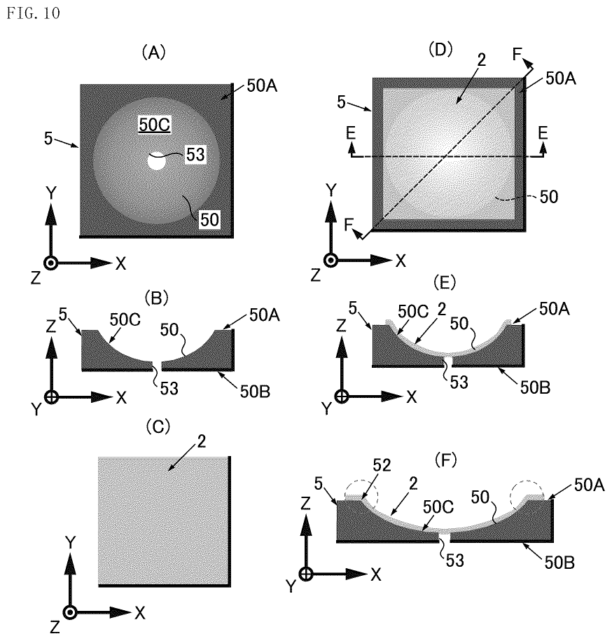

FIG. 10 illustrates a first modification example of the first manufacturing method of the imaging device 1 in a case where a portion of the solid-state imaging element 2 extends to the outside from the curved housing section 50. (A) of FIG. 10 illustrates an example of a planar configuration of the seating 5 before mounting. (B) of FIG. 10 illustrates an example of a cross-sectional configuration of the seating 5 before the mounting. (C) of FIG. 10 illustrates an example of a planar configuration of the solid-state imaging element 2 before the mounting. (D) of FIG. 10 illustrates an example of a planar configuration of the imaging device 1 in which the solid-state imaging element 2 is mounted on the curved housing section 50 of the seating 5. (E) of FIG. 10 illustrates an example of a cross-sectional configuration of the imaging device 1 taken along a line E-E illustrated in (D) of FIG. 10. (F) of FIG. 10 illustrates an example of a cross-sectional configuration of the imaging device 1 taken along a line F-F illustrated in (D) of FIG. 10.

First, as illustrated in (A) and (B) of FIG. 10, the seating 5 is formed. The seating 5 includes the curved housing section 50.

Meanwhile, as illustrated in (C) of FIG. 10, the solid-state imaging element 2 is formed.

Next, as illustrated in (D) to (F) of FIG. 10, the solid-state imaging element 2 is mounted in a curved shape on the curved housing section 50 of the seating 5.

At this time, as viewed in the arrow-Z direction (hereinafter, simply referred to as “in a plan view”) and in the arrow-Y direction (hereinafter, simply referred to as “in a side view”), a portion of a peripheral edge of the solid-state imaging element 2 extending to the outside from the curved housing section 50 is bent along the front surface 50A of the seating 5. At a boundary edge 52 between the curved housing section 50 and the front surface 50A, stress concentration occurs in the solid-state imaging element 2.

A semiconductor substrate of the solid-state imaging element 2 is thinned to have a thickness of 30 μm or less, and the mounting state is verified. As a result, a crack occurs in the solid-state imaging element 2 in a region of a curvature radius of 100 mm or less in the curved housing section 50, thus causing the imaging device 1 to be defective.

### (2) Second Modification Example of First Manufacturing Method

FIG. 11 illustrates a second modification example of the first manufacturing method in a case where the solid-state imaging element 2 is completely contained in the curved housing section 50. (A) of FIG. 11 illustrates an example of a planar configuration of the seating 5 before mounting. (B) of FIG. 11 illustrates an example of a cross-sectional configuration of the seating 5 before the mounting. (C) of FIG. 11 illustrates an example of a planar configuration of the solid-state imaging element 2 before the mounting. (D) of FIG. 11 illustrates an example of a planar configuration of the imaging device 1 in which the solid-state imaging element 2 is mounted on the curved housing section 50 of the seating 5. (E) of FIG. 11 illustrates an example of a cross-sectional configuration of the imaging device 1 taken along a line E-E illustrated in (D) of FIG. 11. (F) of FIG. 11 illustrates an example of a cross-sectional configuration of the imaging device 1 taken along a line F-F illustrated in (D) of FIG. 11.

First, as illustrated in (A) and (B) of FIG. 11, the seating 5 is formed. The seating 5 includes the curved housing section 50.

Meanwhile, as illustrated in (C) of FIG. 11, the solid-state imaging element 2 is formed. The solid-state imaging element 2 is formed relatively into a size that allows the solid-state imaging element 2 to be housed in the curved housing section 50.

Next, as illustrated in (D) to (F) of FIG. 11, the solid-state imaging element 2 is mounted in a curved shape on the curved housing section 50 of the seating 5.

At this time, in a plan view and in a side view, the solid-state imaging element 2 is contained in the curved housing section 50, and the solid-state imaging element 2 is formed entirely in a curved shape along the curved shape of the curved housing section 50. In other words, a peripheral edge of the solid-state imaging element 2 does not reach the boundary edge 52 and is not bent.

According to the imaging device 1 formed as described above, a crack does not occur in the Si substrate of the solid-state imaging element 2 even when the Si substrate is thinned to have a thickness of 30 μm or less and when the curvature radius of the curved housing section 50 reaches a region of 15 mm or less. This allows for obtainment of non-defective imaging device 1.

### (3) Material of Seating 5

The seating 5 used for the curved mounting is formed by a material for which a thermal load in a mounting process and a thermal variation in a market environment are taken into consideration. In other words, the seating 5 is formed by a material that enables thermal expansion coefficients to be aligned as much as possible not to cause a stress due to a temperature change on the solid-state imaging element 2.

For example, when the Si substrate is used for the solid-state imaging element 2, the seating 5 is formed by Si. Si is optimum in that Si minimizes a thermal stress. In a case where Si is not used, it may be possible to form the seating 5 using a material having a thermal expansion coefficient close to the thermal expansion coefficient of Si of 4.15×10⁻⁶/°C.

In addition, in selecting the material of the seating 5, easiness in working, material cost, working cost, seating weight, rigidity, seating thinning, and the like are taken into consideration. Specific examples of the practically available material of the seating 5 include an inorganic insulator, a semiconductor material, a metal material, a resin material, and a ceramic material.

The semiconductor material includes carbon (C), silicon carbide (SiC), and the like. It may be possible to use, as the metal material, one or more metals selected from aluminum (Al), copper (Cu), brass, and titanium (Ti), or an alloy including one or more metals. The metal material is excellent in heat dissipation.

The resin material includes acrylic, polystyrene, polycarbonate, polypropylene, and the like. The resin material is excellent in cost reduction and weight reduction.

The ceramic material includes aluminum oxide (Al₂O₃), and the like. The ceramic material requires high cost, but is excellent in durability, heat dissipation, and the like.

### (4) Overall Configuration of Curved Housing Section 50

In the seating 5, the structure of the front surface of the curved housing section 50 is important. For example, the presence of a protrusion on the curved surface of the curved housing section 50 causes stress concentration to the solid-state imaging element 2 with the protrusion as an origin, thus causing the solid-state imaging element 2 to be easily damaged.

Even if the solid-state imaging element 2 is not damaged, the curved shape of the solid-state imaging element 2 is deformed due to the protrusion, and a deviation occurs on the image-forming surface of the module lens by an amount of the deformation, thus causing the resolution to be degraded.

Accordingly, the front surface of the curved shape of the curved housing section 50 is formed into a smooth front surface where no protrusion is present.

The smooth front surface may be formed using polishing working, grinding working, polishing buff working, wheel working, electrochemical polishing working, or the like. The front surface of a region of the curved housing section 50 in contact with the solid-state imaging element 2 has a maximum roughness/height of at least 1 μm or less. Preferably, the maximum roughness/height is 0.5 μm or less; more preferably, the maximum roughness/height is 0.1 μm or less.

Here, the maximum height/roughness is based on the definitions specified in the Japanese Industrial standard or JIS B0601:2013.

### (5) Third Modification Example of First Manufacturing Method

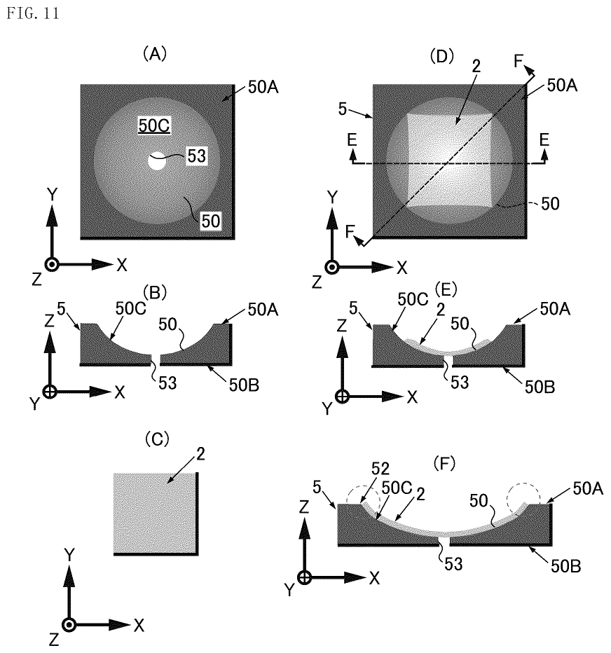

FIG. 12 illustrates a third modification example of the first manufacturing method in which the solid-state imaging element 2 is mounted on the curved housing section 50. (A) of FIG. 12 illustrates an example of a planar configuration of the seating 5 before mounting. (B) of FIG. 12 illustrates an example of a cross-sectional configuration of the seating 5 before the mounting. (C) of FIG. 12 illustrates an example of a cross-sectional configuration of the imaging device 1 in which the solid-state imaging element 2 is mounted on the curved housing section 50 of the seating 5 by utilizing a pressure difference due to depressurization. (D) of FIG. 12 illustrates an example of a cross-sectional configuration of the imaging device 1 in which the solid-state imaging element 2 is mounted on the curved housing section 50 of the seating 5 by utilizing a pressure difference due to pressurization.

First, as illustrated in (A) and (B) of FIG. 12, the seating 5 is formed. The seating 5 includes the curved housing section 50. The ventilation section 53 is formed at a middle part close to the center position of the front surface 50A of the seating 5, in other words, at a middle part of the curved housing section 50. The ventilation section 53 is formed as a through-opening penetrating from the front surface 50A to the back surface 50B opposed to the front surface 50A. Meanwhile, as illustrated in (C) of FIG. 11, the solid-state imaging element 2 is formed.

The solid-state imaging element 2 is placed on the curved housing section 50 of the seating 5 (see (C) of FIG. 12). Here, a vacuum device 600 is connected to the ventilation section 53 formed in the curved housing section 50 of the seating 5.

As described above, the unillustrated film 3 (see FIGS. 3A and 3B) is disposed between the solid-state imaging element 2 and the curved housing section 50. A gas is released by the vacuum device 600 through the ventilation section 53 from the inside of a cavity closed by the film 3, the solid-state imaging element 2, and the curved housing section 50. This causes the inside of the cavity to be depressurized, and, as illustrated in (C) of FIG. 12, the pressure difference causes the solid-state imaging element 2 to be curved along the curved shape of the curved housing section 50, and thus the solid-state imaging element 2 is mounted in the curved housing section 50.

In addition, the solid-state imaging element 2 is placed on the curved housing section 50 of the seating 5 (see (D) of FIG. 12). Here, the nozzle 610 is disposed at a position opposed in the arrow-Z direction to the curved housing section 50 of the seating 5.

The film 3 and the solid-state imaging element 2 are pressurized by a gas blown from the nozzle 610. As the gas, for example, air, an inert gas, or the like may be practically used. The nozzle 610 is connected to an unillustrated gas generation device. When air is used as the gas, a compressor is used as the gas generation device.

As illustrated in (D) of FIG. 10, the pressure difference causes the solid-state imaging element 2 to be curved along the curved shape of the curved housing section 50, and thus the solid-state imaging element 2 is mounted in the curved housing section 50. At this time, the gas in the cavity is released through the ventilation section 53.

### (6) First Configuration of Seating 5

FIG. 13 is a diagram describing a first configuration according to a modification example of the seating 5. (A) of FIG. 13 illustrates an example of a planar configuration of the seating 5 before mounting. (B) of FIG. 13 illustrates an example of a cross-sectional configuration of the seating 5 before the mounting.

First, as illustrated in (A) and (B) of FIG. 13, the seating 5 is formed. The seating 5 includes the curved housing section 50. The ventilation section 53 is formed at a middle part close to the center position of the front surface 50A of the seating 5, in other words, at a middle part of the curved housing section 50. The ventilation section 53 is formed as a through-opening penetrating from the front surface 50A to the back surface 50B.

Further, the embedded member 54 is formed in an embedded state in the ventilation section 53. A porous (porous) material is used for the embedded member 54. The porous material is a material in which a large number of fine holes are formed. To be described in detail, for example, fine powders of Al₂O₃, stainless steel (SUS), or the like are sintered in a ventilated state to obtain the porous material.

In the same manner as the step illustrated in (C) of FIG. 12 mentioned above, the pressure difference due to the depressurization causes the solid-state imaging element 2 to be curved along the curved shape of the curved housing section 50 with use of such a seating 5, thus allowing the solid-state imaging element 2 to be mounted in the curved housing section 50.

In addition, in the same manner as the step illustrated in (D) of FIG. 12 mentioned above, the pressure difference due to the pressurization causes the solid-state imaging element 2 to be curved along the curved shape of the curved housing section 50 with use of such a seating 5, thus allowing the solid-state imaging element 2 to be mounted in the curved housing section 50.

### (7) Fourth Modification Example of First Manufacturing Method

FIG. 14 illustrates a fourth modification example of the first manufacturing method in which the solid-state imaging element 2 is mounted on the curved housing section 50 (A) of FIG. 14 illustrates an example of a planar configuration of the seating 5 before mounting. (B) of FIG. 14 illustrates an example of a cross-sectional configuration of the seating 5 before the mounting. (C) of FIG. 14 illustrates an example of a cross-sectional configuration at the time when the solid-state imaging element 2 is placed on the curved housing section 50 of the seating 5. (D) of FIG. 14 illustrates an example of a cross-sectional configuration of the imaging device 1 in which the solid-state imaging element 2 is mounted on the curved housing section 50 of the seating 5.

First, as illustrated in (A) and (B) of FIG. 14, the seating 5 is formed. The seating 5 includes the curved housing section 50. A pocket 55 is formed around a middle part close to the center position of the front surface 50A of the seating 5. In a side view, the pocket 55 is formed in a groove shape that is further recessed from the front surface of the curved housing section 50 in the incident direction of the incident light L. In addition, here, the pocket 55 is formed in a circular ring shape in a plan view, although not particularly limited thereto. The pocket 55 takes in an excess of a glue 51 formed in the curved housing section 50 to effectively suppress or prevent an overflow of the glue 51 from between the curved housing section 50 and the solid-state imaging element 2.

Meanwhile, the solid-state imaging element 2 is formed.

As illustrated in (C) of FIG. 14, the glue 51 is formed in the curved housing section 50 of the seating 5, and, further, the solid-state imaging element 2 is placed on the curved housing section 50.

For example, the above-described pressure difference is generated, and the solid-state imaging element 2 is formed in a curved shape along the curved shape of the curved housing section 50, as illustrated in (D) of FIG. 14. The glue 51 allows the solid-state imaging element 2 to be adhered to the inside of the curved housing section 50 to form the imaging device 1 in which the solid-state imaging element 2 is mounted on the seating 5.

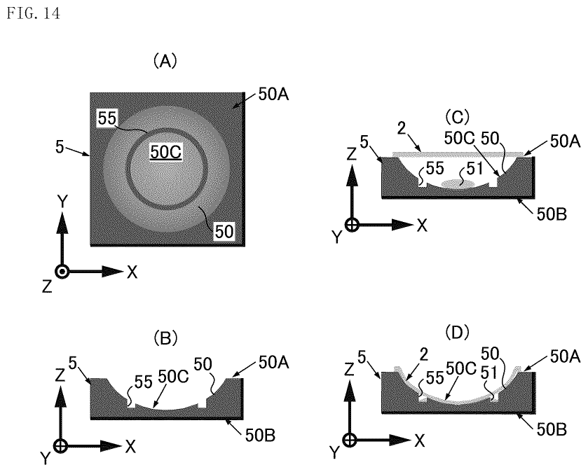

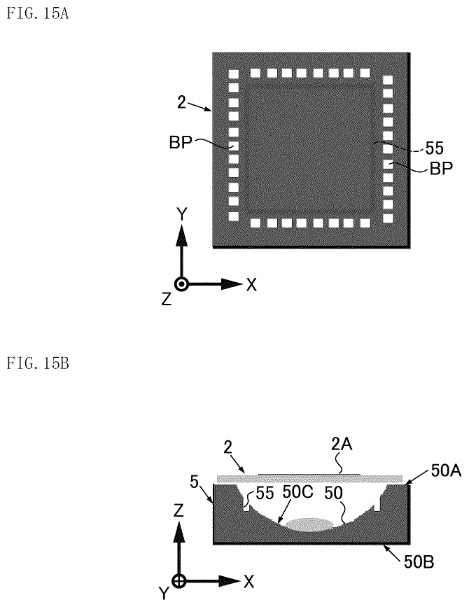

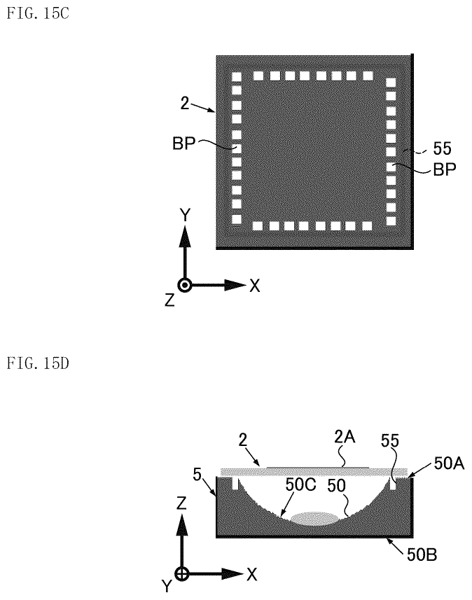

Here, description is given of a variation of a position at which the pocket 55 is disposed. FIG. 15A illustrates an example of a planar configuration of the seating 5 describing a variation of a position at which the pocket 55 is disposed. FIG. 15B illustrates an example of a cross-sectional configuration of the seating 5 illustrated in FIG. 15A. FIG. 15C illustrates an example of another planar configuration of the seating 5. FIG. 15D illustrates an example of a cross-sectional configuration of the seating 5 illustrated in FIG. 15C. FIG. 15E illustrates an example of still another planar configuration of the seating 5. FIG. 15F illustrates an example of a cross-sectional configuration of the seating 5 illustrated in FIG. 15E.

As illustrated in FIGS. 15A and 15B, a plurality of element terminals (bonding pads) BP is arrayed in a peripheral part of the solid-state imaging element 2. In a plan view and in a side view, the pocket 55 is disposed at a position that does not overlap the element terminals BP inside the array of the element terminals BP.

Here, the pocket 55 is formed in a groove shape. The pocket 55 is formed to have a depth (groove depth), for example, in a range of several μm or more and several tens of μm or less from the curved surface 50C. In addition, the pocket 55 is formed to have a width (groove width), for example, in a range of several tens of μm or more and several hundreds of μm or less.

In addition, as illustrated in FIGS. 15C and 15D, the pocket 55 is disposed at a position that does not overlap the element terminals BP outside the array of the element terminals BP, in a plan view and in a side view.

Further, as illustrated in FIGS. 15E and 15F, the pocket 55 is disposed at positions that do not overlap the element terminals BP inside and outside the array of the element terminals BP, in a plan view and in a side view.

### (8) Second Configuration of Seating 5

FIG. 16 is a diagram describing a second configuration according to the modification example of the seating 5. (A) of FIG. 16 illustrates an example of a cross-sectional configuration of the seating 5 and the solid-state imaging element 2 before mounting. (B) of FIG. 16 illustrates an example of an enlarged cross-sectional configuration of a main part of the seating 5 and the solid-state imaging element 2.

As illustrated in (A) and (B) of FIG. 16, the stepped part 56 is formed in the curved housing section 50 of the seating 5. The stepped part 56 is formed as a positioning guide that abuts a peripheral end of the solid-state imaging element 2 placed in the curved housing section 50 to perform positioning of the solid-state imaging element 2 with respect to the curved housing section 50.

According to the seating 5 configured as described above, it is possible to perform positioning of the solid-state imaging element 2 on the curved housing section 50 easily and accurately by using the stepped part 56.

### (9) Third Configuration of Seating 5

FIG. 17 illustrates an example of a planar configuration describing a third configuration according to the modification example of the seating 5.

As illustrated in FIG. 17, the mark 57 is formed in a peripheral part of the front surface 50A of the seating 5. The mark 57 is formed as an alignment mark to perform positioning of the curved housing section 50 of the seating 5 and the solid-state imaging element 2. Positioning of the mark 57 is performed with respect to an outline shape of the solid-state imaging element 2, for example.

According to the seating 5 configured as described above, the use of the mark 57 makes it possible to perform positioning of the solid-state imaging element 2 on the curved housing section 50 easily and accurately.

It is to be noted that, in the seating 5, the ventilation section 53, the pocket 55, or the stepped part 56 described above to be brought into contact with the solid-state imaging element 2 has a rounding shape in which corner portions have roundness. It is possible, in a region having the rounding shape, to effectively suppress or prevent stress concentration that occurs in the solid-state imaging element 2 formed in a curved shape and subjected to the stress.

### <2. Second Embodiment>

Description is given, with reference to FIGS. 18 to 21A, of the imaging device 1 and a method of manufacturing the imaging device 1 according to the second embodiment of the present disclosure.

### [Configuration of Imaging Device 1]

FIG. 18 illustrates an example of a cross-sectional configuration of the imaging device 1 according to the second embodiment.

As illustrated in FIG. 18, the imaging device 1 includes an element section 100 and an optical section 200.

The element section 100 includes the seating 5, the solid-state imaging element 2 mounted on the curved housing section 50 of the seating 5, the wiring substrate 7, and the film 3 disposed between the seating 5 and the solid-state imaging element 2. Meanwhile, the optical section 200 includes a lens group 210, a lens holder 211 that holds the lens group 210, an actuator 212, and an infrared cut filter (IRCF) 215.

### (1) Configuration of Element Section 100

An FPC is used for the wiring substrate 7. The FPC is formed using a polyimide film, or the like as a base material, and has flexibility (plasticity). The FPC is an electric circuit substrate in which a plurality of wiring layers and components are printed on the base material. The FPC is thin, lightweight, and bendable and stretchable.

The wiring substrate 7 is mounted with a semiconductor component, e.g., an LSI (Large Scale Integration) such as a capacitor, a resistor, and an auto focus driver to drive the actuator 212, and with an electric element 72 such as a connector to output an imaging signal from the solid-state imaging element 2 to an external device.

The wiring substrate 7 is disposed on the curved housing section 50 with the solid-state imaging element 2 interposed therebetween, and is formed in a curved shape in the same manner as the solid-state imaging element 2. In addition, the wiring substrate 7 is formed in a curved shape and then firmly fixed to the seating 5 using an underfill material.

Here, the solid-state imaging element 2 is configured by, for example, a CSP (Chip Scale Package) structure that pulls out the element terminals BP from directly under the back surface. In this case, fine solder balls are arrayed on the back surface 2B opposed to the light-receiving surface 2A of the solid-state imaging element 2. That is, the solid-state imaging element 2 adopts a ball grid array (BGA: Ball Grid Array) structure. A solder pad is disposed at a position corresponding to the solder ball of the wiring substrate 7.

The solid-state imaging element 2 is placed on the wiring substrate 7, and the solder ball and the solder pad that are to be paired are bonded, thus allowing the solid-state imaging element 2 to be mounted on the wiring substrate 7. An ultrasonic vibration method, a thermocompression bonding method, or the like is usable for the bonding.

According to the imaging device 1 configured as described above, the coupling using the wire 9 (see FIG. 8) is not used. This makes it possible to reduce the size (chip size) of the solid-state imaging element 2, because the wire 9 is not led around to the outside of the solid-state imaging element 2.

In addition, a wiring length is reduced in coupling the solid-state imaging element 2 and the wiring substrate 7 to each other, thus making it possible to achieve a higher operation speed of the imaging device 1.

In addition, the solid-state imaging element 2 having the above-described CSP structure may be a stacked solid-state imaging element to which a logic substrate is attached. In this case, the thickness of the solid-state imaging element 2 is increased; however, it is possible to reduce an area of a peripheral circuit disposed around the light-receiving surface 2A in the solid-State imaging element 2.

According to the solid-state imaging element 2 configured as described above, it is possible to increase the number of acquisitions from semiconductor wafers in the manufacturing process. In addition, it is possible to allocate a large-scale circuit with added value to a side of the logic substrate.

In the same manner as the imaging device 1 according to the first embodiment, the seating 5 includes the curved housing section 50 on the front surface 50A. The curved shape of the curved housing section 50 is formed in a shape that allows for the CRA to be vertical incidence at any image height, in a manner corresponding to an optical design of the module lens.

When the solid-state imaging element 2 or the like is formed in a curved shape by a pressure difference between gases, the seating 5 is provided with the ventilation section 53 that releases a gas from space closed by the solid-state imaging element 2, the film 3, and the curved housing section 50 of the seating 5. The ventilation section 53 is formed by a through-hole penetrating from the curved surface 50C of the curved housing section 50 of the seating 5 to the back surface 50B opposed thereto.

The embedded member 54 is embedded in the ventilation section 53 (see (A) and (B) of FIG. 13). The embedded member 54 may be a porous material.

When the ventilation section 53 of the seating 5 is clogged with the embedded member 54, it is possible to effectively suppress or prevent a phenomenon in which the incident light L of a long wavelength passes through the thinned solid-state imaging element 2 and is reflected by the seating 5 to cause a shape of the curved housing section 50 to be reflected therein.

In addition, the clogging of the ventilation section 53 makes it possible to effectively suppress or prevent loss of a stress balance, near the ventilation section 53, of the base of the solid-state imaging element 2 mounted on the curved housing section 50 of the seating 5. It is therefore possible, in the solid-state imaging element 2, to effectively suppress or prevent deterioration of a dark current and a white spot.

Further, when the embedded member 54 is formed by a material having high thermal conductivity, it is possible to improve a heat dissipation effect.

From such a viewpoint, as the embedded member 54, one or more materials are used, which are selected from among a material having a reflectance close to that of the seating 5, a material that is able to fill the entire region of the ventilation section 53 without generation of a void, and a material having high thermal conductivity.

The film 3 is formed by a thin organic material having a high sealing property and plasticity. In the manufacturing process, the film 3 seals, completely covers, and is attached to the curved housing section 50 of the seating 5.

In addition, a glue is applied to both of the front surface and the back surface of the film 3. According to the imaging device 1 configured as described above, it is possible, in a manufacturing method (mounting method) using a pressure difference due to depressurization or pressurization, to effectively suppress or prevent gas leakage (e.g., air leakage) at the time when mounting the solid-state imaging element 2 that is smaller than the curved housing section 50 of the seating 5.

As the glue to be applied to the film 3, as described above, one or more resin glues selected from an epoxy-based resin, an acrylic-based resin, and a cyan-based resin are used. As the glue, a UV-cured type, a temperature-cured type, a time-cured type, or the like is usable, and no particular limitation is made on the cured type.

In a case where the UV-cured type is adopted as the glue, the seating 5 is formed by a material that transmits UV. UV is irradiated from the side of the back surface 50B of the seating 5, for example.

### (2) Configuration of Optical Section 200

In the optical section 200, the lens group 210 includes at least one or more lenses. The lens group 210 forms an image of a subject on the light-receiving surface 2A of the solid-state imaging element 2 fixed in a curved shape to the curved housing section 50 of the seating 5.

The curved light-receiving surface 2A of the solid-state imaging element 2 has an effect of reducing image plane distortion of the lens. It is therefore possible, in terms of lens design, to achieve a reduction in the number of lenses, a reduction in the height of the optical section 200, higher resolution, and the like.

In FIG. 18, the actuator 212 drives a predetermined lens included in the lens group 210 in one or more directions selected from an up-down direction, a right-left direction, and a front-rear direction. That is, the actuator 212 achieves functions such as autofocus and hand shake correction in the imaging device 1.

It is to be noted that the actuator 212 may drive the seating 5 and the solid-state imaging element 2 in one or more directions selected from the up-down direction, the right-left direction, and the front-rear direction to achieve the functions such as autofocus and hand shake correction. In addition, the imaging device 1 may be configured as an imaging device of the hand shake correction type that inclines (tilts) all components of the lens group 210, the seating 5, and the solid-state imaging element 2.

The infrared cut filter 215 cuts light of a wavelength component other than a wavelength component of visible light, in particular, light of a wavelength component of infrared light, for the incident light L condensed by the lens group 210.

### (3) Configuration of Wiring Substrate 7

The wiring substrate 7 seals and covers, without a double-sided adhesive film being interposed, all of openings of the curved housing section 50 of the seating 5, and is fixed to the front surface 50A around the curved housing section 50 of the seating 5. For example, the collet 620 (see FIG. 5) is used for the fixing. The resin glue may be used to fix the seating 5 and the wiring substrate 7 to each other.

According to the imaging device 1 configured as described above, it is possible, in a manufacturing method (mounting method) using a pressure difference due to depressurization or pressurization, to effectively suppress or prevent gas leakage (e.g., air leakage) at the time when mounting the solid-state imaging element 2 that is smaller than the curved housing section 50 of the seating 5.

It is to be noted that the resin glue may be applied to a back surface of the wiring substrate 7 on the side of the solid-state imaging element 2. The method of curing the glue is as described above.

However, in a case where the resin glue is applied to a region of the back surface of the wiring substrate 7 to be in contact with the curved surface 50C of the seating 5, the resin glue applied to the front surface 50A of the seating 5 needs to be partially cured. For this reason, it is preferable to use a UV-cured type resin glue. That is, the resin glue is applied to the entire region, on a side of the back surface of the wiring substrate 7, to be in contact with the seating 5, and, for the fixing of the wiring substrate 7 to a flat part of the seating 5, UV irradiation is performed only on the flat part.

[Configuration according to Modification Example of Imaging Device 1]

FIG. 19 illustrates an example of a cross-sectional configuration of an imaging device according to a modification example of the second embodiment.

As illustrated in FIG. 19, the imaging device 1 includes a resin film 4 containing an infrared-absorbing material instead of the infrared cut filter 215. The resin film 4 is formed in a curved shape on the light-receiving surface 2A of the solid-state imaging element 2 along the curved shape of the light-receiving surface 2A.

In addition, the above-described infrared cut filter 215 may be molded into a curved shape by a lens-molding method from a glass material having an infrared absorption function.

According to the imaging device 1 configured as described above, providing the resin film 4 makes it possible to effectively suppress or prevent degradation in characteristics due to the incident light L that is obliquely incident.

In addition, the infrared cut filter 215 molded into a plate shape is not required, thus making it possible to improve the degree of freedom in the lens design.

### [Workings and Effects]

In the imaging device 1 according to the second embodiment, it is possible to obtain workings and effects similar to the workings and effects obtained by the imaging device 1 according to the first embodiment.

### [First Manufacturing Method of Imaging Device 1]

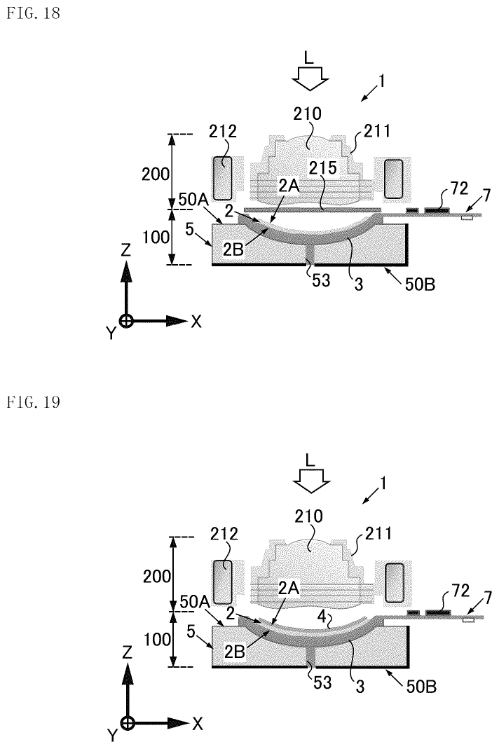

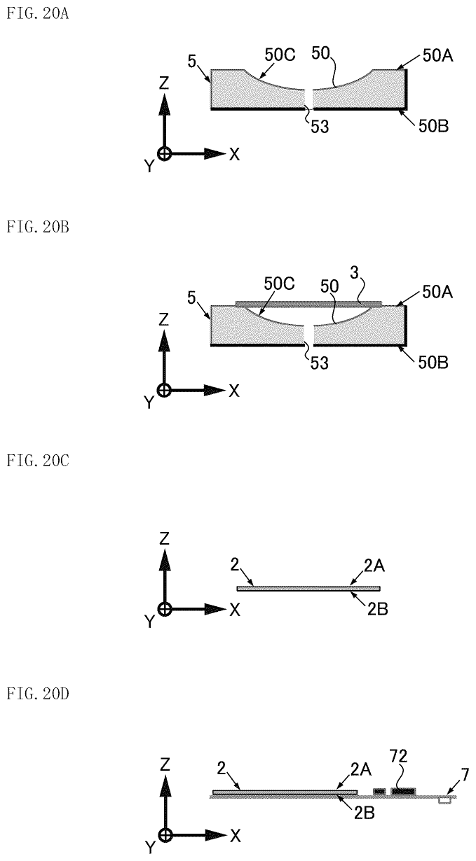

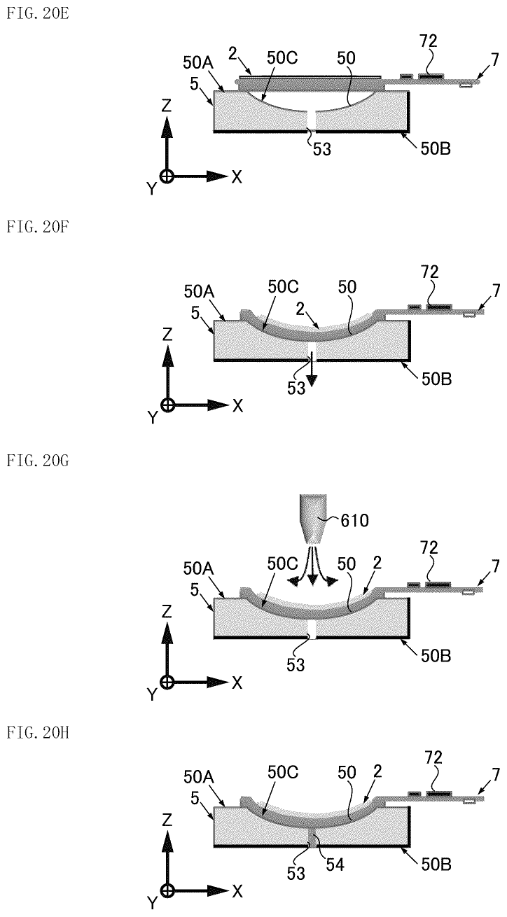

Description is given, with reference to FIGS. 20A and 20H, of a first manufacturing method of the imaging device 1 according to the second embodiment. FIGS. 20A to 20H each illustrate an example of a cross-section of a step describing the first manufacturing method. The first manufacturing method is as follows.

First, as illustrated in FIG. 20A, the seating 5 is formed. The seating 5 includes the curved housing section 50. In addition, the seating 5 includes the ventilation section 53. The embedded member 54 formed by a porous material may be embedded in the ventilation section 53.

As illustrated in FIG. 20B, the film 3 that seals an opening of the curved housing section 50 of the seating 5 is formed. The film 3 is formed by an organic material. A glue is applied to both surfaces of the film 3.

Meanwhile, as illustrated in FIG. 20C, the solid-state imaging element 2 is formed separately from the seating 5. An unillustrated fine solder ball is formed on the back surface 2B opposed to the light-receiving surface 2A of the solid-state imaging element 2.

As illustrated in FIG. 20D, the wiring substrate 7 is prepared, and the solid-state imaging element 2 is mounted on the wiring substrate 7. An unillustrated solder pad is formed on the wiring substrate 7. Bonding the solder ball to the solder pad allows the solid-state imaging element 2 to be mounted on the wiring substrate 7. An ultrasonic vibration method or a thermocompression bonding method is used for the bonding.

Here, the wiring substrate 7 is manufactured by a thin film printing technique. Specifically, a Cu foil is attached to a base material, and a circuit pattern is formed on the Cu foil. An etching technique is used to form the circuit pattern. The above-described electric element 72 is then mounted on the wiring substrate 7.

As illustrated in FIG. 20E, the wiring substrate 7 is adhered to the film 3 that is attached to the seating 5. At this time, the mark 57 (see FIG. 17) is formed on the seating 5, and thus an optical alignment mechanism is used to perform accurate positioning of the wiring substrate 7 with respect to the seating 5.

It is to be noted that a positioning alignment mark may be formed on the film 3. In addition, the stepped part 56 (see FIGS. 16A and 16B) that serves as a positioning guide may be formed on the seating 5. Further, a positioning pin may be disposed on one of the seating 5 or the wiring substrate 7, and a positioning hole may be disposed on the other thereof to cause the positioning pin and the positioning hole to be fitted to each other, thus allowing for the positioning.

An end of the solid-state imaging element 2 mounted on the wiring substrate 7 may be fixed by an underfill material, for example. In this case, it is possible to effectively suppress or prevent a possibility that the solid-state imaging element 2 may be damaged due to an impact, or the like.

As illustrated in FIG. 20F, the film 3, the solid-state imaging element 2, and the wiring substrate 7 are formed in a curved shape along the curved surface 50C of the curved housing section 50 of the seating 5. Here, the inside of the curved housing section 50 is depressurized through the ventilation section 53, and the pressure difference causes the film 3, the solid-state imaging element 2, and the wiring substrate 7 to be formed in a curved shape (see (C) of FIG. 12). The glue is then cured, and the film 3, the solid-state imaging element 2, and the wiring substrate 7 are fastened to the seating 5.

In addition, as illustrated in FIG. 20G, the film 3, the solid-state imaging element 2, and the wiring substrate 7 may be formed in a curved shape by a pressure difference due to pressurization of a gas from the nozzle 610.

As the glue, as described above, one or more resin glues selected from an epoxy-based resin, an acrylic-based resin, and a cyan-based resin are used. As the glue, a UV-cured type, a temperature-cured type, a time-cured type, or the like is usable, and no particular limitation is made on the cured type.

In a case where the UV-cured type is adopted as the glue, the seating 5 is formed by a material that transmits UV. UV is irradiated from the side of the back surface 50B of the seating 5, for example.

In a case where the temperature-cured type or the time-cured type is adopted as the glue, the seating 5 is formed by a material that does not transmit UV.

As illustrated in FIG. 20H, the embedded member 54 is embedded in the ventilation section 53 of the seating 5. When the ventilation section 53 is clogged with the embedded member 54, it is possible to effectively suppress or prevent a phenomenon in which the incident light L of a long wavelength passes through the thinned solid-state imaging element 2 and is reflected by the seating 5 to cause a shape of the curved housing section 50 to be reflected therein. In addition, the clogging of the ventilation section 53 makes it possible to effectively suppress or prevent loss of a stress balance, near the ventilation section 53, of the base of the solid-state imaging element 2 mounted on the curved housing section 50 of the seating 5. It is therefore possible, in the solid-state imaging element 2, to effectively suppress or prevent deterioration of a dark current and a white spot.

Further, when the embedded member 54 is formed by a material having high thermal conductivity, it is possible to improve a heat dissipation effect.

From such a viewpoint, as the embedded member 54, one or more materials are used, which are selected from among a material having a reflectance close to that of the seating 5, a material that is able to fill the entire region of the ventilation section 53 without generation of a void, and a material having high thermal conductivity.

In addition, as the material having high thermal conductivity, a high-melting-point material may be used for the embedded member 54, and the embedded member 54 may be pasted. As the high-melting-point material, Sn, Ag, Cu, Pb, or the like is usable.

In addition, the embedded member 54 may be formed on a metal that is disposed at a position corresponding to the ventilation section 53 on a side of the wiring substrate 7. As the embedded member 54, Cu formed on the metal by plating processing is used. In addition, as the embedded member 54, for example, an electrically-conductive resin to be used for an underfill material or

### The Like May Be Used.

It is to be noted that, in the second embodiment, the wiring substrate 7 and the film 3 are disposed between the solid-state imaging element 2 and the seating 5. When materials and thicknesses of the wiring substrate 7 and the film 3 are appropriately set, the incident light L is not transmitted to the curved housing section 50 of the seating 5. That is, it is possible to effectively suppress or prevent an opening shape of the seating 5 being reflected therein. In this case, it is possible to reduce manufacturing cost of the imaging device 1.

Next, a module is mounted as a component on the seating 5 (see FIG. 18). An unillustrated spacer that fixes the actuator 212 to the wiring substrate 7 is disposed on the wiring substrate 7.

The spacer is formed by, for example, a resin material such as a matte black synthetic resin or a synthetic resin colored into matte black. It is therefore possible, in the spacer, to suppress reflection of the incident light L. In addition, the spacer is able to reduce stray light.

In addition, a fixing agent may be filled between the spacer and the solid-state imaging element 2. The fixing agent is able to enhance adhesive force between the solid-state imaging element 2 and the wiring substrate 7.

After the fixing agent is fastened, attachment of the actuator 212 including the infrared cut filter 215 and the lens group 210 is performed onto the spacer, as illustrated in FIG. 18.

When the series of steps is finished, the imaging device 1 is completed.

### [Second Manufacturing Method of Imaging Device 1]

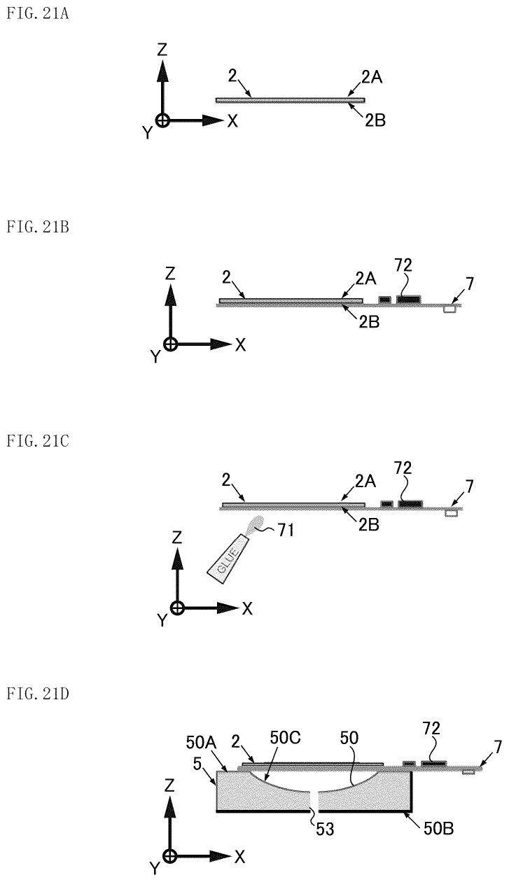

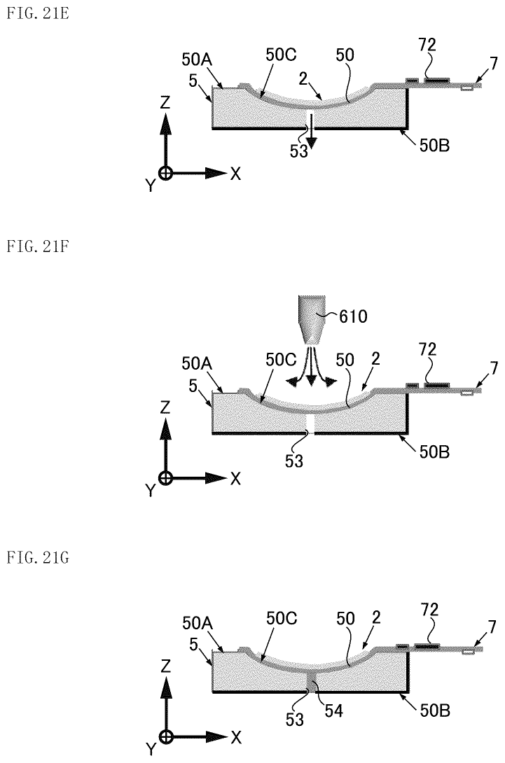

Description is given, with reference to FIGS. 21A to 20G, of a second manufacturing method of the imaging device 1 according to the second embodiment. FIGS. 21A to 20G each illustrate an example of a cross-section of a step describing the second manufacturing method. The second manufacturing method is as follows.

First, as illustrated in FIG. 21A, the solid-state imaging element 2 is formed. An unillustrated fine solder ball is formed on the back surface 2B opposed to the light-receiving surface 2A of the solid-state imaging element 2.

As illustrated in FIG. 21B, the wiring substrate 7 is prepared, and the solid-state imaging element 2 is mounted on the wiring substrate 7. An unillustrated solder pad is formed on the wiring substrate 7. Bonding the solder ball to the solder pad allows the solid-state imaging element 2 to be mounted on the wiring substrate 7. An ultrasonic vibration method or a thermocompression bonding method is used for the bonding. The above-described electric element 72 is mounted on the wiring substrate 7.

As illustrated in FIG. 21C, a glue 71 is applied to the back surface of the wiring substrate 7 on a side of the seating 5. It is to be noted that the glue 71 may be applied to the curved surface 50C of the curved housing section 50 of the seating 5.

As illustrated in FIG. 21D, the wiring substrate 7 is adhered to the seating 5. The wiring substrate 7 is formed on the front surface 50A of the seating 5 to completely clog the opening of the curved housing section 50. Accordingly, the film 3 formed in the step illustrated in FIG. 20B of the first manufacturing method is not required because the film 3 is substituted by the wiring substrate 7.

As illustrated in FIG. 21E, the solid-state imaging element 2 and the wiring substrate 7 are formed in a curved shape along the curved surface 50C of the curved housing section 50 of the seating 5. Here, the inside of the curved housing section 50 is depressurized through the ventilation section 53, and the pressure difference causes the solid-state imaging element 2 and the wiring substrate 7 to be formed in a curved shape.

In addition, as illustrated in FIG. 21F, the film 3, the solid-state imaging element 2, and the wiring substrate 7 may be formed in a curved shape by a pressure difference due to pressurization of a gas from the nozzle 610.

As illustrated in FIG. 21G, the embedded member 54 is embedded in the ventilation section 53 of the seating 5.

Thereafter, in the same manner as the first manufacturing method, attachment of the actuator 212 including the infrared cut filter 215 and the lens group 210 as well as an unillustrated spacer is performed.

When the series of steps is finished, the imaging device 1 is completed.

### [Workings and Effects]

In the manufacturing method of the imaging device 1 according to the second embodiment, it is possible to obtain workings and effects similar to the workings and effects obtained by the manufacturing method of the imaging device 1 according to the first embodiment.

### <3. Third Embodiment>

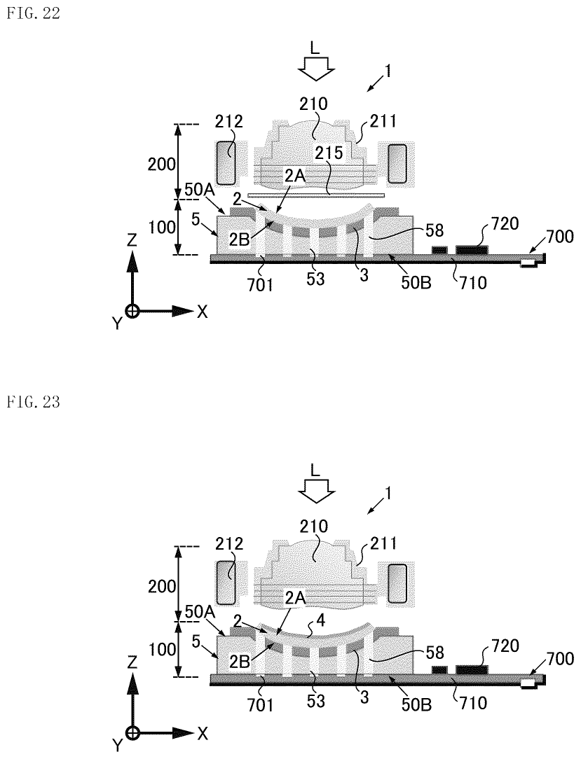

Description is given, with reference to FIGS. 22 to 68, of the imaging device 1 and a method of manufacturing the imaging device 1 according to the third embodiment of the present disclosure.

### [Configuration of Imaging Device 1]

FIG. 22 illustrates an example of a cross-sectional configuration of the imaging device 1 according to the third embodiment. The third embodiment is a practical application example of the imaging device 1 and the method of manufacturing the imaging device 1 according to the second embodiment.

As illustrated in FIG. 22, the imaging device 1 includes the element section 100 and the optical section 200, in the same manner as the imaging device 1 according to the second embodiment. Further, the element section 100 includes the solid-state imaging element 2, the film 3, the seating 5, and a mounting substrate 700 to be mounted with the seating 5.

### (1) Configuration of Element Section 100

The solid-state imaging element 2 is configured by, for example, the CSP structure that pulls out the element terminals BP from directly under the back surface. In this case, fine solder balls are arrayed on the back surface 2B opposed to the light-receiving surface 2A of the solid-state imaging element 2. That is, the solid-state imaging element 2 adopts the BGA structure.

In addition, the solid-state imaging element 2 may adopt a land grid array (Cu-LGA: Cu-Land Grid Array) structure in which Cu pins are arrayed as terminals.

According to the imaging device 1 configured as described above, the coupling using the wire 9 (see FIG. 8) is not used. This makes it possible to reduce the size of the solid-state imaging element 2, because the wire 9 is not led around to the outside of the solid-state imaging element 2.

In addition, a wiring length is reduced in coupling the solid-state imaging element 2 and the mounting substrate 700 to each other, thus making it possible to achieve a higher operation speed of the imaging device 1.

The infrared cut filter 215 (see FIG. 22) is disposed on the side of the light-receiving surface 2A of the solid-state imaging element 2. As the infrared cut filter 215, there is adopted an absorption type, a multilayer film type in which dielectric films of different refractive indexes are stacked, or a hybrid type in which both of the absorption type and the multilayer film type are combined.

In addition, the solid-state imaging element 2 having the CSP structure may be a stacked solid-state imaging element to which a logic substrate is attached. In this case, the thickness of the solid-state imaging element 2 is increased; however, it is possible to reduce an area of a peripheral circuit disposed around the light-receiving surface 2A in the solid-state imaging element 2.

According to the solid-state imaging element 2 configured as described above, it is possible to increase the number of acquisitions from semiconductor wafers in the manufacture. In addition, it is possible to allocate a large-scale circuit with added value to the side of the logic substrate.

In the same manner as the imaging device 1 according to the first embodiment, the seating 5 includes the curved housing section 50 on the front surface 50A. The curved shape of the curved housing section 50 is formed in a shape that allows for the CRA to be vertical incidence at any image height, in a manner corresponding to an optical design of the module lens.

In the curved light-receiving surface 2A of the solid-state imaging element 2, providing such a seating 5 allows for an effect of reducing image plane distortion of the lens. It is therefore possible, in terms of lens design, to achieve a reduction in the number of lenses, a reduction in the height of the optical section 200, higher resolution, and the like.

In addition, the curved housing section 50 of the seating 5 may be formed in a curved shape in which the normal line of the curved surface 50C coincides with respect to the CRA of the module lens.

In addition, according to the seating 5 having such a shape, even in the case of high image height, a principal light beam is incident on the solid-state imaging element 2 vertically, thus making it possible to effectively suppress sensitivity loss due to vignetting in a pixel of the solid-state imaging element 2 and degradation in image quality such as oblique light color mixture.

When the solid-state imaging element 2 or the like is formed in a curved shape by a pressure difference between gases, the seating 5 is provided with the ventilation section 53 that releases a gas from space closed by the solid-state imaging element 2, the film 3, and the curved housing section 50 of the seating 5. The ventilation section 53 is formed by a through-hole penetrating from the curved surface 50C of the curved housing section 50 of the seating 5 to the back surface 50b opposed thereto.

The embedded member 54 is embedded in the ventilation section 53 (see (A) and (B) of FIG. 13). The embedded member 54 may be a porous material.

In addition, the ventilation section 53 of the seating 5 is used, for example, as a gas vent in the manufacturing process, and a plurality of ventilation sections 53 is arrayed and serves also as a hole array. An electric conductor 58 is embedded in the ventilation section 53 that serves also as the hole array. One end of the electric conductor 58 is electrically coupled to the solid-state imaging element 2, and another end of the electric conductor 58 is electrically coupled to the mounting substrate 700.

The film 3 is formed by a thin organic material having a high sealing property and plasticity. In the manufacturing process, the film 3 seals, completely covers, and is attached to the curved housing section 50 of the seating 5.

In addition, a glue is applied to both of the front surface and the back surface of the film 3. According to the imaging device 1 configured as described above, it is possible, in a manufacturing method (mounting method) using a pressure difference due to depressurization or pressurization, to effectively suppress or prevent gas leakage (e.g., air leakage) at the time when mounting the solid-state imaging element 2 that is smaller than the curved housing section 50 of the seating 5.

As the glue to be applied to the film 3, as described above, one or more resin glues selected from an epoxy-based resin, an acrylic-based resin, and a cyan-based resin are used. As the glue, a UV-cured type, a temperature-cured type, a time-cured type, or the like is usable, and no particular limitation is made on the cured type.

In a case where the UV-cured type is adopted as the glue, the seating 5 is formed by a material that transmits UV. UV is irradiated from the side of the back surface 50B of the seating 5, for example.

In the film 3, an opening 3H is formed at a position to serve as an electrical coupling region between the solid-state imaging element 2 and the mounting substrate 700. A peripheral location of the opening 3H of the film 3 is adhered by a glue to the solid-state imaging element 2. This makes it possible to effectively suppress or prevent gas leakage from the opening 3H of the film 3.

In a case where the seating 5 is provided with the ventilation section 53 (illustration thereof is omitted here) aside from the hole array, the solid-state imaging element 2 is mounted on the seating 5, and then the embedded member 54 is embedded in the ventilation section 53 (see (a) and (b) of FIG. 13).

When the ventilation section 53 of the seating 5 is clogged with the embedded member 54, it is possible to effectively suppress or prevent a phenomenon in which the incident light L of a long wavelength passes through the thinned solid-state imaging element 2 and is reflected by the seating 5 to cause a shape of the curved housing section 50 to be reflected therein.

In addition, the clogging of the ventilation section 53 makes it possible to effectively suppress or prevent loss of a stress balance, near the ventilation section 53, of the base of the solid-state imaging element 2 mounted on the curved housing section 50 of the seating 5. It is therefore possible, in the solid-state imaging element 2, to effectively suppress or prevent deterioration of a dark current and a white spot.

Further, when the embedded member 54 is formed by a material having high thermal conductivity, it is possible to improve a heat dissipation effect.

From such a viewpoint, as the embedded member 54, one or more materials are used, which are selected from among a material having a reflectance close to that of the seating 5, a material that is able to fill the entire region of the ventilation section 53 without generation of a void, and a material having high thermal conductivity.

In addition, as the material having high thermal conductivity, a high-melting-point material may be used for the embedded member 54, and the embedded member 54 may be pasted. As the high-melting-point material, Sn, Ag, Cu, Pb, or the like is usable.

In addition, the embedded member 54 may be formed on a metal that is disposed at a position corresponding to the ventilation section 53 on the side of the wiring substrate 7. As the embedded member 54, Cu formed on the metal by plating processing is used. In addition, as the embedded member 54, for example, an electrically-conductive resin to be used for an underfill material or the like may be used.

### (2) Configuration of Optical Section 200

The optical section 200 includes the lens group 210, the lens holder 211 that holds the lens group 210, the actuator 212, and the infrared cut filter 215.

The components of the optical section 200 are the same as or substantially the same as the components of the optical section 200 of the imaging device 1 according to the second embodiment. Descriptions thereof are therefore omitted here.

### (3) Configuration of Mounting Substrate 700

The mounting substrate 700 is mounted with the seating 5. The mounting substrate 700 includes a base material 710, a mounting terminal (land) 701 disposed on a surface of the base material 710 on the side of the seating 5, a coupling connector 702, and an unillustrated wiring layer. Further, in the mounting substrate 700, an electric element 720 such as a semiconductor component described above is mounted on the base material 710.

The base material 710 is formed by an epoxy resin, for example.

The mounting terminal 701 is electrically coupled to the unillustrated element terminal BP of the solid-state imaging element 2 through the electric conductor 58 embedded in the ventilation section 53 of the seating 5, the solder ball described above, and the like. The mounting terminal 701 is formed by Cu, for example.

The coupling connector 702 is electrically coupled to the mounting terminal 701, the electric element 720, and the like through the wiring layer.

[Configuration according to Modification Example of Imaging Device 1]

FIG. 23 illustrates an example of a cross-sectional configuration of an imaging device according to a modification example of the third embodiment.

As illustrated in FIG. 23, the imaging device 1 includes the resin film 4 containing an infrared-absorbing material instead of the infrared cut filter 215. The resin film 4 is formed in a curved shape on the light-receiving surface 2A of the solid-state imaging element 2 along the curved shape of the light-receiving surface 2A.

In addition, the above-described infrared cut filter 215 may be molded into a curved shape by a lens-molding method from a glass material having an infrared absorption function.

According to the imaging device 1 configured as described above, providing the resin film 4 makes it possible to effectively suppress or prevent degradation in characteristics due to the incident light L that is obliquely incident.

In addition, the infrared cut filter 215 molded into a plate shape is not required, thus making it possible to improve the degree of freedom in the lens design.

### [Workings and Effects]

In the imaging device 1 according to the third embodiment, it is possible to obtain workings and effects similar to the workings and effects obtained by the imaging device 1 according to the second embodiment.

### [First Manufacturing Method of Imaging Device 1]

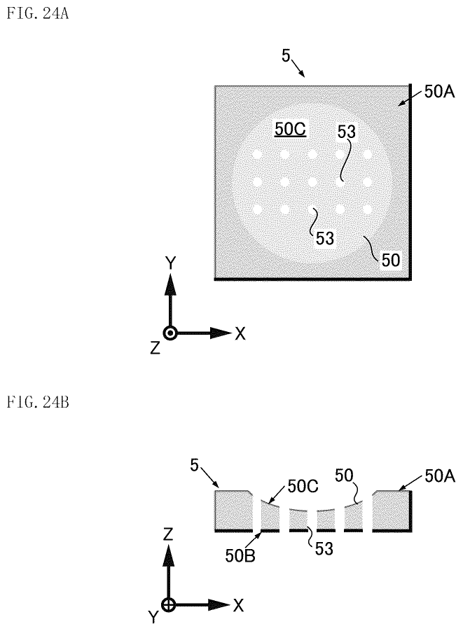

Description is given, with reference to FIGS. 24A and 24B to 32, of a first manufacturing method of the imaging device 1 according to the third embodiment. FIGS. 24A and 24B to 32 each illustrate an example of a step describing the first manufacturing method. The first manufacturing method is as follows.

First, as illustrated in FIGS. 24A and 24B, the seating 5 is formed. The seating 5 includes the curved housing section 50. In addition, the seating 5 includes the ventilation section 53. In the curved housing section 50, the plurality of ventilation sections 53 is arrayed with a predetermined interval apart from each other in the arrow-X direction and in the arrow-Y direction, and is formed as a hole array.

In addition, the seating 5 is formed by an insulating material, or an insulating film is formed on at least an inner wall of the ventilation section 53 of the seating 5 in a case where the seating 5 has electrical conductivity.

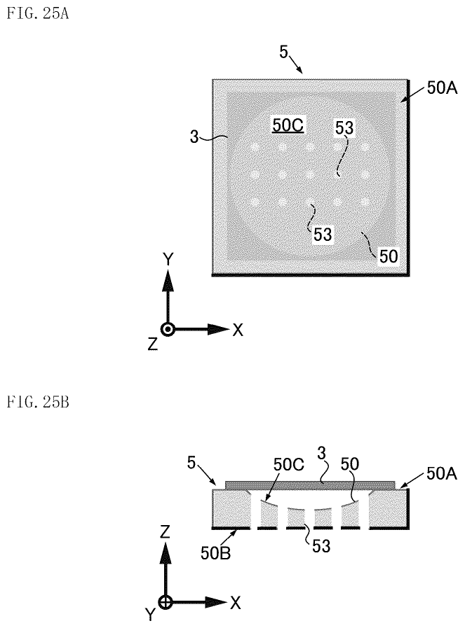

As illustrated in FIGS. 25A and 25B, the film 3 that seals an opening of the curved housing section 50 of the seating 5 is formed. The film 3 is formed by an organic material. A glue is applied to both surfaces of the film 3.

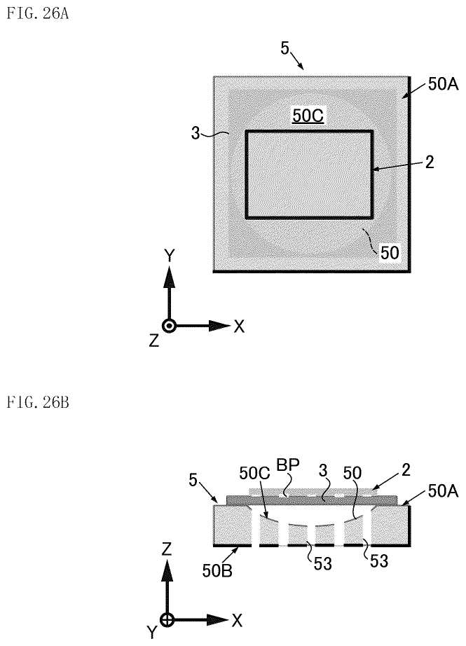

Meanwhile, the solid-state imaging element 2 is formed separately from the seating 5. An unillustrated fine solder ball is formed on the back surface 2B opposed to the light-receiving surface 2A of the solid-state imaging element 2 (see FIGS. 26A and 26B).

As illustrated in FIGS. 26A and 26B, the solid-state imaging element 2 is adhered to the film 3.

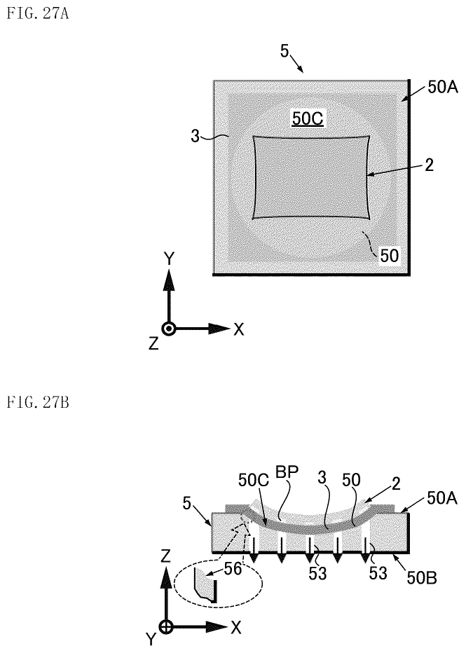

As illustrated in FIGS. 27A and 27B, the film 3 and the solid-state imaging element 2 are formed in a curved shape along the curved surface 50C of the curved housing section 50 of the seating 5. Here, the inside of the curved housing section 50 is depressurized through the ventilation section 53, and the pressure difference causes the film 3 and the solid-state imaging element 2 to be formed in a curved shape.

In addition, the stepped part 56 is formed in advance in the seating 5, and an end of the solid-state imaging element 2 and the stepped part 56 coincide with each other upon the formation into a curved shape. That is, positioning of the solid-state imaging element 2 is performed in a self-alignment manner with respect to the curved housing section 50 of the seating 5.

The glue is then cured, and the film 3 and the solid-state imaging element 2 are fastened to the seating 5.

Here, as illustrated in FIG. 28, the film 3 and the solid-state imaging element 2 may be formed in a curved shape by a pressure difference due to pressurization of a gas from the nozzle 610.

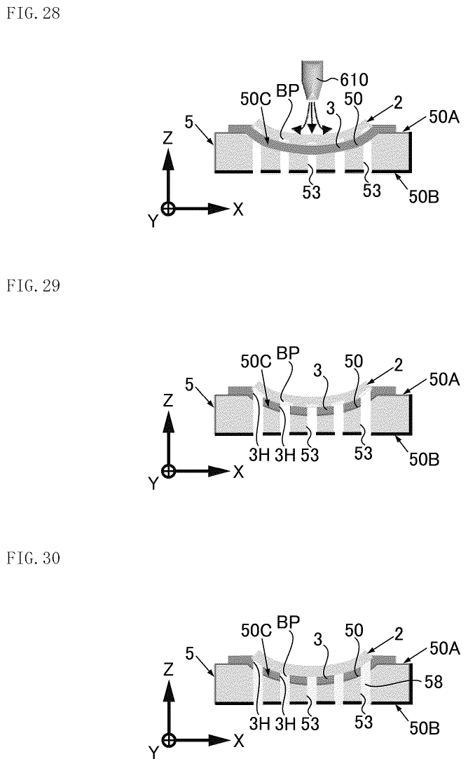

Next, as illustrated in FIG. 29, the opening 3H is formed in the film 3 at a position corresponding to the element terminal BP of the solid-state imaging element 2. The opening 3H is formed by performing etching through the ventilation section 53 from the side of the back surface 50B of the seating 5. Wet etching or dry etching is used as the etching.

It is to be noted that, when the opening 3H is formed, the element terminal BP is not deviated from the position of the opening 3H. In addition, when an insulating film is formed on the inner wall of the ventilation section 53, the insulating film is formed to have a thickness that does not cause a reduction in film thickness due to etching.

As illustrated in FIG. 30, the electric conductor 58 is formed inside the ventilation section 53 of the seating 5. One end of the electric conductor 58 on the side of the solid-state imaging element 2 is electrically coupled to the element terminal BP of the solid-state imaging element 2.

The electric conductor 58 is formed by Cu, for example, and Cu is formed as a film by plating processing, for example.

In addition, the electric conductor 58 may be formed by selective pasting of a high-melting-point material such as Sn, Ag, Cu, or Pb. In this case, the electric conductor 58 is electrically coupled to the element terminal BP by solder bonding. When the high-melting-point material is used, one or more layers selected from Au and nickel (Ni) are formed on a surface of the element terminal BP. This makes it possible to improve solder bondability (solder wettability).

As illustrated in FIG. 31, the mounting substrate 700 is prepared, and positioning of the solid-state imaging element 2 and the seating 5 are performed with respect to the mounting substrate 700. An unillustrated glue is partially applied to at least one of the mounting substrate 700 or the solid-state imaging element 2. For example, a resin glue is used as the glue. The glue is cured after the mounting substrate 700 and the seating 5 are attached to each other.

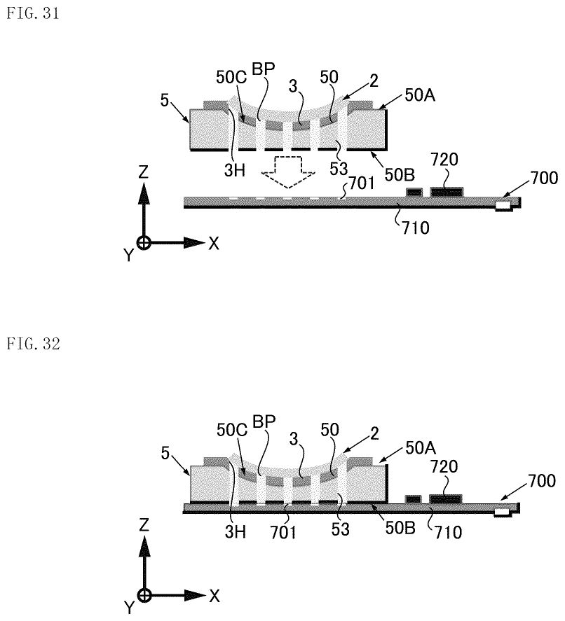

Subsequently, as illustrated in FIG. 32, the solid-state imaging element 2 is mounted on the mounting substrate 700. Upon the mounting, the one end of the electric conductor 58 formed in the ventilation section 53 of the seating 5 is electrically coupled to the element terminal BP of the solid-state imaging element 2, and the other end of the electric conductor 58 is electrically coupled to the mounting terminal 701 of the mounting substrate 700. An ultrasonic vibration method or a thermocompression bonding method is used for this coupling.

In consideration of damage to a barrier metal or the like, the coupling of the one end of the electric conductor 58 and the coupling of the other end thereof are preferably performed at the same time.

In addition, the seating 5 is firmly fastened to the mounting substrate 700 using an underfill material.

As illustrated in FIG. 22 mentioned above, attachment of the actuator 212 including the infrared cut filter 215 and the lens group 210 is performed onto an unillustrated spacer.

When the series of steps is finished, the imaging device 1 is completed.

### [Second Manufacturing Method of Imaging Device 1]

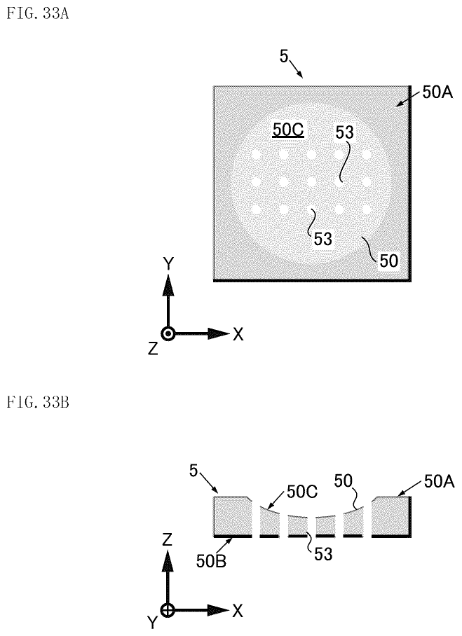

Description is given, with reference to FIGS. 33A and 33B to 40, of a second manufacturing method of the imaging device 1 according to the third embodiment. FIGS. 33A and 33B to 40 each illustrate an example of a step describing the second manufacturing method. The second manufacturing method is as follows.

First, as illustrated in FIGS. 33A and 33B, the seating 5 is formed. The seating 5 includes the curved housing section 50. In addition, the seating 5 includes the ventilation section 53. In the curved housing section 50, the plurality of ventilation sections 53 is arrayed with a predetermined interval apart from each other in the arrow-X direction and in the arrow-Y direction, and is formed as a hole array.

In addition, the seating 5 is formed by an insulating material, or an insulating film is formed on at least an inner wall of the ventilation section 53 of the seating 5 in a case where the seating 5 has electrical conductivity.

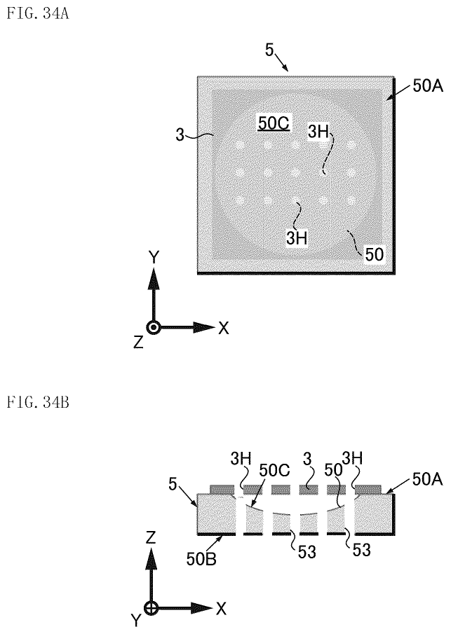

As illustrated in FIGS. 34A and 34B, the film 3 that seals an opening of the curved housing section 50 of the seating 5 is formed. The film 3 is formed by an organic material. A glue is applied to both surfaces of the film 3.

Here, in the second manufacturing method, the opening 3H is formed in advance in the film 3.

Meanwhile, the solid-state imaging element 2 is formed separately from the seating 5. An unillustrated fine solder ball is formed on the back surface 2B opposed to the light-receiving surface 2A of the solid-state imaging element 2 (see FIGS. 35A and 35B). Positioning of the solder ball is performed in the opening 3H of the film 3; the solder ball is positioned in the opening 3H.

As illustrated in FIGS. 35A and 35B, the solid-state imaging element 2 is adhered to the film 3.

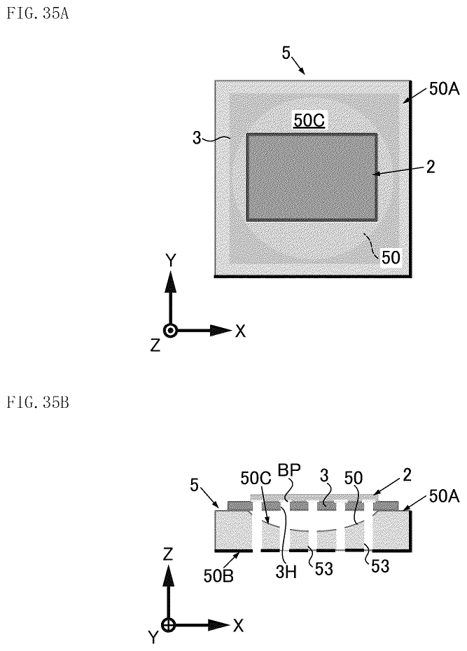

As illustrated in FIGS. 36A and 36B, the film 3 and the solid-state imaging element 2 are formed in a curved shape along the curved surface 50C of the curved housing section 50 of the seating 5. Here, the inside of the curved housing section 50 is depressurized through the ventilation section 53, and the pressure difference causes the film 3 and the solid-state imaging element 2 to be formed in a curved shape.

In addition, the stepped part 56 is formed in advance in the seating 5, and an end of the solid-state imaging element 2 and the stepped part 56 coincide with each other upon the formation into a curved shape. That is, positioning of the solid-state imaging element 2 is performed in a self-alignment manner with respect to the curved housing section 50 of the seating 5.

The glue is then cured, and the film 3 and the solid-state imaging element 2 are fastened to the seating 5.

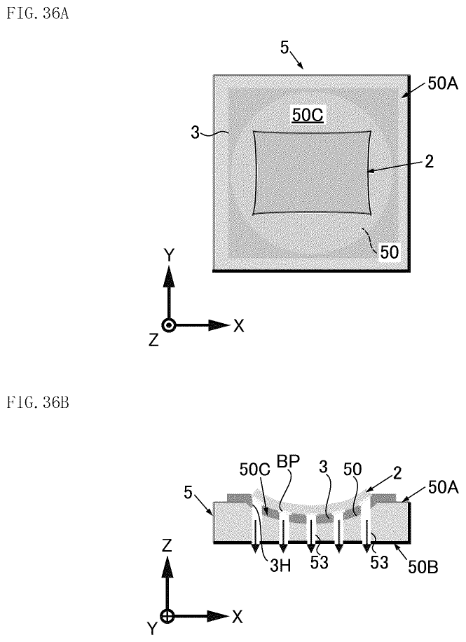

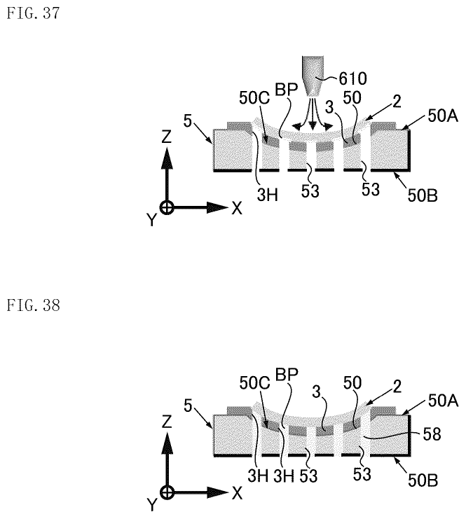

Here, as illustrated in FIG. 37, the film 3 and the solid-state imaging element 2 may be formed in a curved shape by a pressure difference due to pressurization of a gas from the nozzle 610.

As illustrated in FIG. 38, the electric conductor 58 is formed inside the ventilation section 53 of the seating 5. One end of the electric conductor 58 on the side of the solid-state imaging element 2 is electrically coupled to the element terminal BP of the solid-state imaging element 2.

The electric conductor 58 is formed by Cu, for example, and Cu is formed as a film by plating processing, for example.

In addition, the electric conductor 58 may be formed by selective pasting of a high-melting-point material such as Sn, Ag, Cu, or Pb. In this case, the electric conductor 58 is electrically coupled to the element terminal BP by solder bonding. When the high-melting-point material is used, one or more layers selected from Au and Ni are formed on a surface of the element terminal BP. This makes it possible to improve solder bondability.

As illustrated in FIG. 39, the mounting substrate 700 is prepared, and positioning of the solid-state imaging element 2 and the seating 5 are performed with respect to the mounting substrate 700. An unillustrated glue is partially applied to at least one of the mounting substrate 700 or the solid-state imaging element 2. For example, a resin glue is used as the glue. The glue is cured after the mounting substrate 700 and the seating 5 are attached to each other.

Subsequently, as illustrated in FIG. 40, the solid-state imaging element 2 is mounted on the mounting substrate 700. Upon the mounting, the one end of the electric conductor 58 formed in the ventilation section 53 of the seating 5 is electrically coupled to the element terminal BP of the solid-state imaging element 2, and the other end of the electric conductor 58 is electrically coupled to the mounting terminal 701 of the mounting substrate 700. An ultrasonic vibration method or a thermocompression bonding method is used for this coupling.

In consideration of damage to a barrier metal or the like, the coupling of the one end of the electric conductor 58 and the coupling of the other end thereof are preferably performed at the same time.

In addition, the seating 5 is firmly fastened to the mounting substrate 700 using an underfill material.

As illustrated in FIG. 22 mentioned above, attachment of the actuator 212 including the infrared cut filter 215 and the lens group 210 is performed onto an unillustrated spacer.

When the series of steps is finished, the imaging device 1 is completed.

### [Third Manufacturing Method of Imaging Device 1]

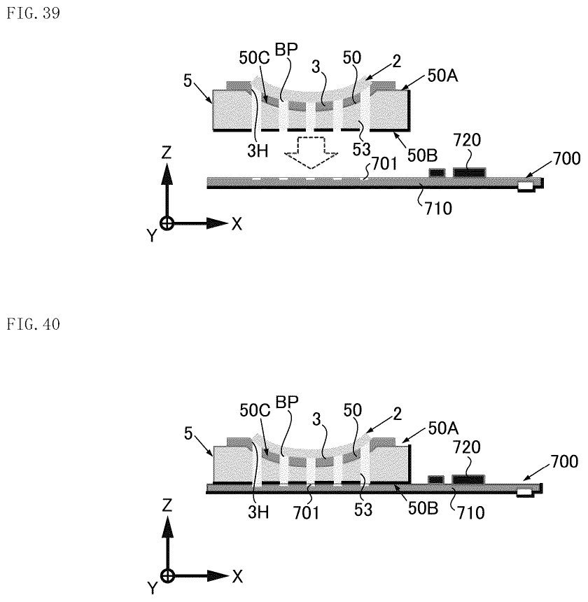

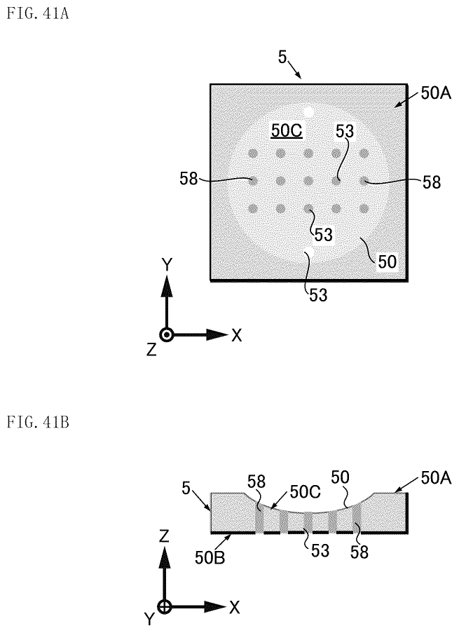

Description is given, with reference to FIGS. 41A and 41B to 49, of a third manufacturing method of the imaging device 1 according to the third embodiment. FIGS. 41A and 41B to 49 each illustrate an example of a step describing the third manufacturing method. The third manufacturing method is as follows.

First, as illustrated in FIGS. 41A and 41B, the seating 5 is formed. The seating 5 includes the curved housing section 50. In addition, the seating 5 includes the ventilation section 53. In the curved housing section 50, the plurality of ventilation sections 53 is arrayed with a predetermined interval apart from each other in the arrow-X direction and in the arrow-Y direction, and is formed as a hole array.

In addition, the seating 5 is formed by an insulating material, or an insulating film is formed on at least an inner wall of the ventilation section 53 of the seating 5 in a case where the seating 5 has electrical conductivity.

The electric conductor 58 is formed inside the ventilation section 53 of the seating 5. The electric conductor 58 is formed by Cu, for example, and Cu is formed as a film by plating processing, for example.

In addition, the electric conductor 58 may be formed by selective pasting of a high-melting-point material such as Sn, Ag, Cu, or Pb. At this time, one of the side of the curved surface 50C or the side of the back surface 50B of the seating 5 may be clogged with a provisional material to prevent leakage of the electric conductor 58 from the ventilation section 53, and then the provisional material may be removed.

In addition, a flat provisional material including a metal at a position corresponding to the ventilation section 53 may be formed on the back surface 50B of the seating 5, and the electric conductor 58 may be selectively formed for the metal. For example, Cu by means of plating processing is used for the electric conductor 58.

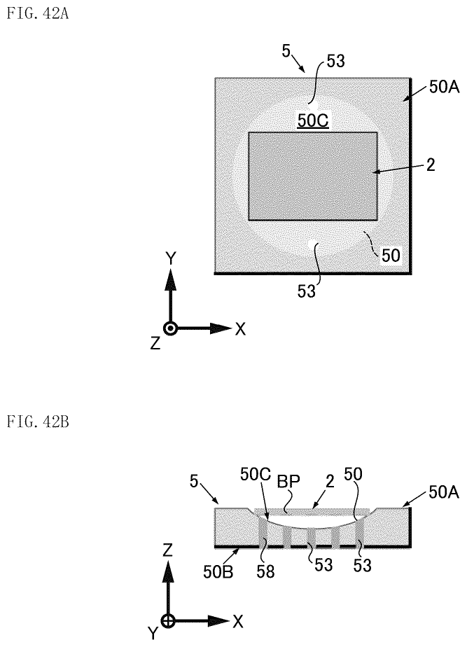

As illustrated in FIGS. 42A and 42B, the solid-state imaging element 2 is placed on the curved housing section 50 of the seating 5.

As illustrated in FIGS. 43A and 43B, the film 3 that seals an opening of the curved housing section 50 of the seating 5 is formed to cover the solid-state imaging element 2. The film 3 is formed by an organic material.

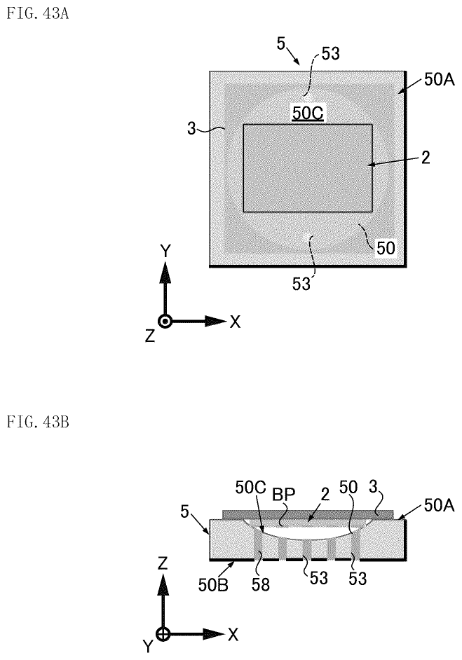

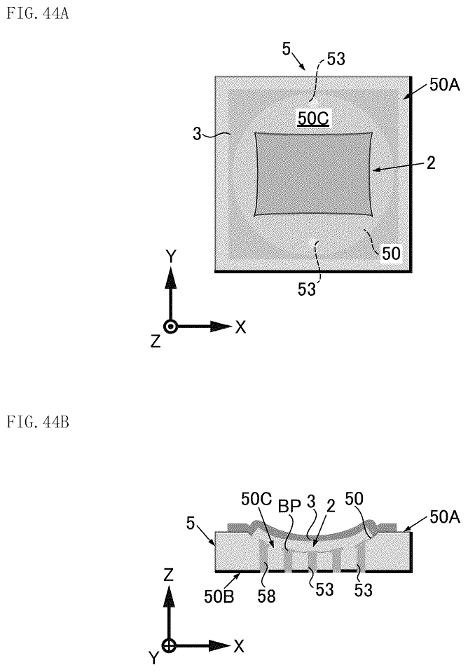

As illustrated in FIGS. 44A and 44B, the film 3 and the solid-state imaging element 2 are formed in a curved shape along the curved surface 50C of the curved housing section 50 of the seating 5. Here, the inside of the curved housing section 50 is depressurized through the ventilation section 53, and the pressure difference causes the film 3 and the solid-state imaging element 2 to be formed in a curved shape.

In addition, the stepped part 56 is formed in advance in the seating 5, and an end of the solid-state imaging element 2 and the stepped part 56 coincide with each other upon the formation into a curved shape. That is, positioning of the solid-state imaging element 2 is performed in a self-alignment manner with respect to the curved housing section 50 of the seating 5. This allows the element terminal BP of the solid-state imaging element 2 to be electrically coupled to an electric conductor 28 of the seating 5.

The glue is then cured, and the film 3 and the solid-state imaging element 2 are fastened to the seating 5.

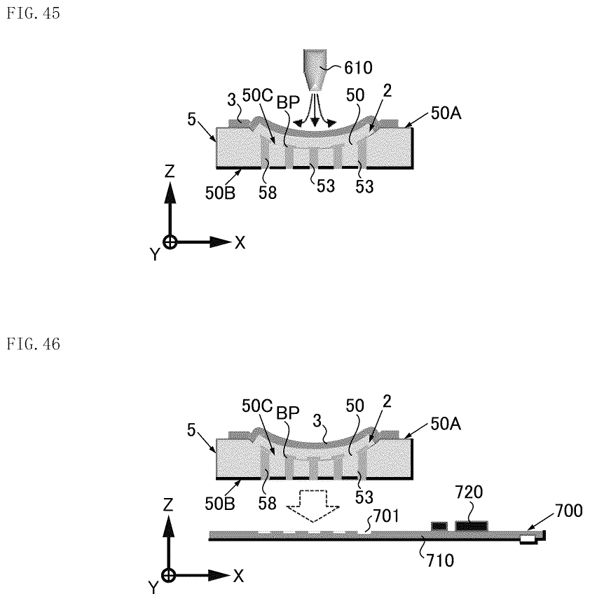

Here, as illustrated in FIG. 45, the film 3 and the solid-state imaging element 2 may be formed in a curved shape by a pressure difference due to pressurization of a gas from the nozzle 610.

As illustrated in FIG. 46, the mounting substrate 700 is prepared, and positioning of the solid-state imaging element 2 and the seating 5 are performed with respect to the mounting substrate 700. An unillustrated glue is partially applied to at least one of the mounting substrate 700 or the solid-state imaging element 2. For example, a resin glue is used as the glue. The glue is cured after the mounting substrate 700 and the seating 5 are attached to each other.

Subsequently, as illustrated in FIG. 47, the solid-state imaging element 2 is mounted on the mounting substrate 700. Upon the mounting, the one end of the electric conductor 58 formed in the ventilation section 53 of the seating 5 is electrically coupled to the element terminal BP of the solid-state imaging element 2, and the other end of the electric conductor 58 is electrically coupled to the mounting terminal 701 of the mounting substrate 700. An ultrasonic vibration method or a thermocompression bonding method is used for this coupling.

In consideration of damage to a barrier metal or the like, the coupling of the one end of the electric conductor 58 and the coupling of the other end thereof are preferably performed at the same time.

In addition, the seating 5 is firmly fastened to the mounting substrate 700 using an underfill material.

As illustrated in FIG. 48, the film 3 is removed.

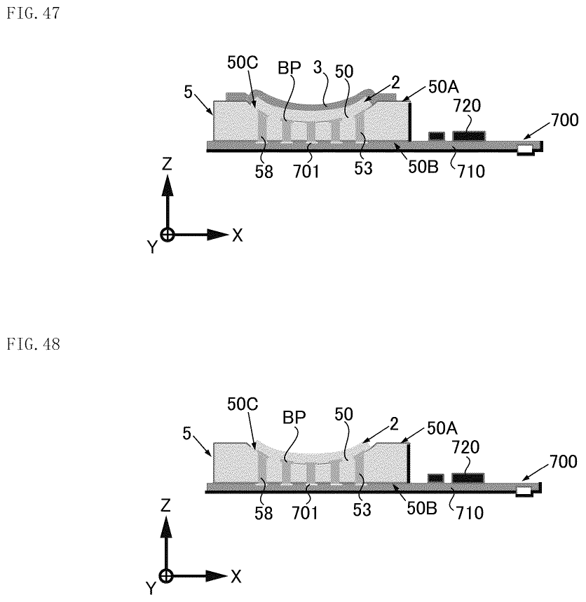

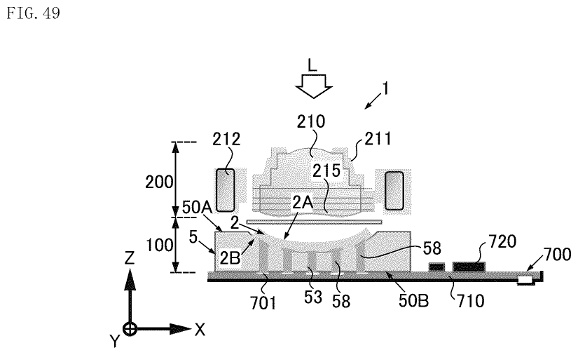

As illustrated in FIG. 49, attachment of the actuator 212 including the infrared cut filter 215 and the lens group 210 is performed onto an unillustrated spacer.

When the series of steps is finished, the imaging device 1 is completed.

### [Fourth Manufacturing Method of Imaging Device 1]

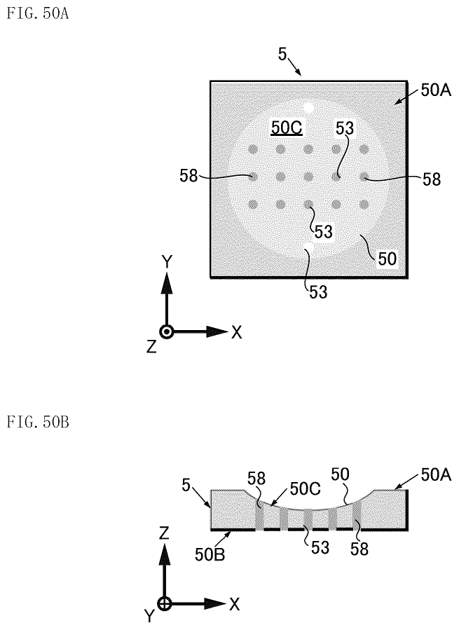

Description is given, with reference to FIGS. 50A and 50B to 57, of a fourth manufacturing method of the imaging device 1 according to the third embodiment. FIGS. 50A and 50B to 57 each illustrate an example of a step describing the fourth manufacturing method. The fourth manufacturing method is as follows.

First, as illustrated in FIGS. 50A and 50B, the seating 5 is formed. The seating 5 includes the curved housing section 50. In addition, the seating 5 includes the ventilation section 53. In most cases, the plurality of ventilation sections 53, in the curved housing section 50, is arrayed with a predetermined interval apart from each other in the arrow-X direction and in the arrow-Y direction, and is formed as a hole array. In addition, some of the ventilation sections 53 are formed simply as a through-hole that releases a gas.

In addition, the seating 5 is formed by an insulating material, or an insulating film is formed on at least an inner wall of the ventilation section 53 of the seating 5 in a case where the seating 5 has electrical conductivity.

The electric conductor 58 is formed inside the ventilation section 53 used as a hole array of the seating 5. The electric conductor 58 is formed by Cu, for example, and Cu is formed as a film by plating processing, for example.

In addition, the electric conductor 58 may be formed by selective pasting of a high-melting-point material such as Sn, Ag, Cu, or Pb. At this time, one of the side of the curved surface 50C or the side of the back surface 50B of the seating 5 is clogged with a provisional material to prevent leakage of the electric conductor 58 from the ventilation section 53, and then the provisional material is removed.

In addition, a flat provisional material including a metal at a position corresponding to the ventilation section 53 may be formed on the back surface 50B of the seating 5, and the electric conductor 58 may be selectively formed for the metal. For example, Cu by means of plating processing is used for the electric conductor 58.

The electric conductor 58 is not formed in the ventilation section 53 not used as the hole array.

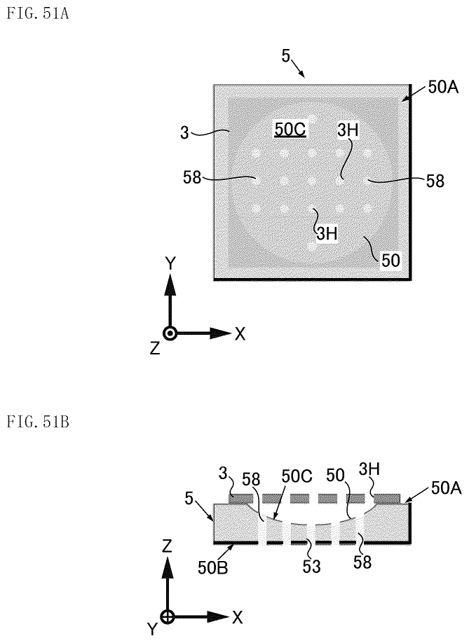

As illustrated in FIGS. 51A and 52B, the film 3 that seals an opening of the curved housing section 50 of the seating 5 is formed. The film 3 is formed by an organic material. A glue is applied to both surfaces of the film 3.

Here, in the fourth manufacturing method, the opening 3H is formed in advance in the film 3.

Meanwhile, the solid-state imaging element 2 is formed separately from the seating 5. As illustrated in FIGS. 52A and 52B, the solid-state imaging element 2 is adhered to the film 3. The element terminal BP or a fine solder ball is formed on the back surface 2B opposed to the light-receiving surface 2A of the solid-state imaging element 2. Positioning of the solder ball is performed in the opening 3H of the film 3; the solder ball is positioned in the opening 3H. The element terminal BP or the fine solder ball is protruded from the surface of the film 3 on the side of the curved surface 50C to the side of the curved surface 50C.

As illustrated in FIGS. 53A and 53B, the film 3 and the solid-state imaging element 2 are formed in a curved shape along the curved surface 50C of the curved housing section 50 of the seating 5. Here, the inside of the curved housing section 50 is depressurized through the ventilation section 53, and the pressure difference causes the film 3 and the solid-state imaging element 2 to be formed in a curved shape. This allows one end of the electric conductor 58 on the side of the solid-state imaging element 2 to be electrically coupled to the element terminal BP of the solid-state imaging element 2.

In addition, the stepped part 56 is formed in advance in the seating 5, and an end of the solid-state imaging element 2 and the stepped part 56 coincide with each other upon the formation into a curved shape. That is, positioning of the solid-state imaging element 2 is performed in a self-alignment manner with respect to the curved housing section 50 of the seating 5.

The glue is then cured, and the film 3 and the solid-state imaging element 2 are fastened to the seating 5.

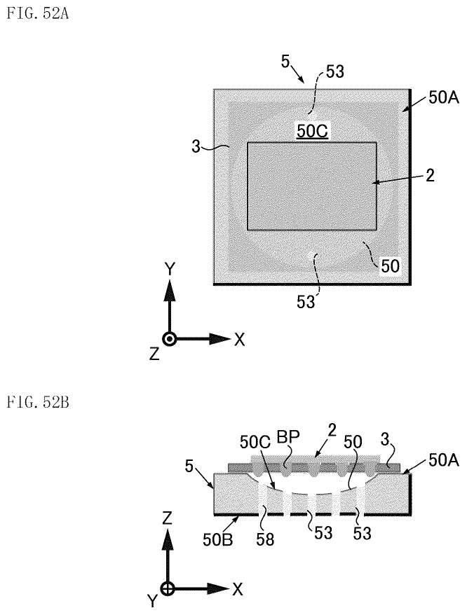

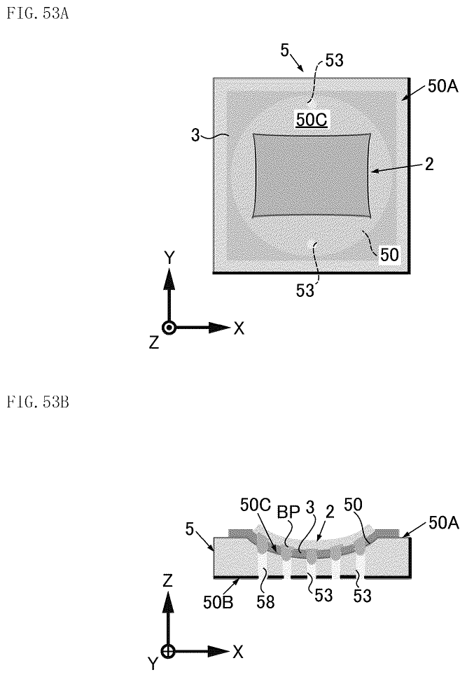

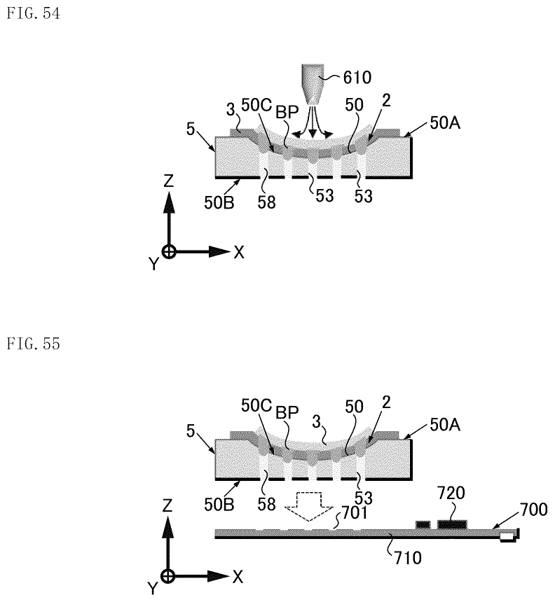

Here, as illustrated in FIG. 54, the film 3 and the solid-state imaging element 2 may be formed in a curved shape by a pressure difference due to pressurization of a gas from the nozzle 610.

As illustrated in FIG. 55, the mounting substrate 700 is prepared, and positioning of the solid-state imaging element 2 and the seating 5 are performed with respect to the mounting substrate 700. An unillustrated glue is partially applied to at least one of the mounting substrate 700 or the solid-state imaging element 2. For example, a resin glue is used as the glue. The glue is cured after the mounting substrate 700 and the seating 5 are attached to each other.

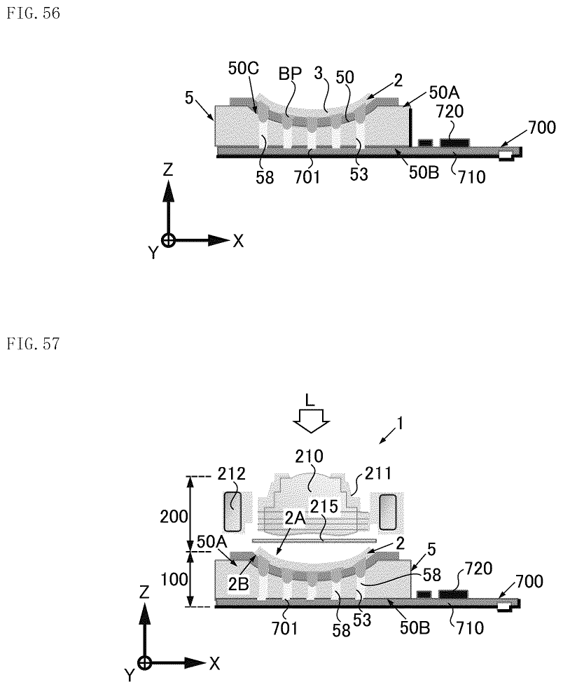

Subsequently, as illustrated in FIG. 56, the solid-state imaging element 2 is mounted on the mounting substrate 700. Upon the mounting, the one end of the electric conductor 58 formed in the ventilation section 53 of the seating 5 is electrically coupled to the element terminal BP of the solid-state imaging element 2, and the other end of the electric conductor 58 is electrically coupled to the mounting terminal 701 of the mounting substrate 700. An ultrasonic vibration method or a thermocompression bonding method is used for this coupling.

In consideration of damage to a barrier metal or the like, the coupling of the one end of the electric conductor 58 and the coupling of the other end thereof are preferably performed at the same time.

In addition, the seating 5 is firmly fastened to the mounting substrate 700 using an underfill material.

As illustrated in FIG. 57, attachment of the actuator 212 including the infrared cut filter 215 and the lens group 210 is performed onto an unillustrated spacer.

When the series of steps is finished, the imaging device 1 is completed.

### [Configuration of Seating 5]

### (1) First Configuration of Seating 5

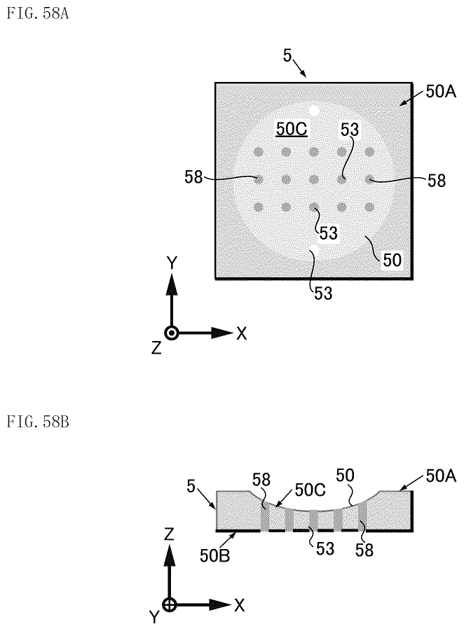

FIG. 58A illustrates an example of a planar configuration of the seating 5 of the imaging device 1 according to the third embodiment. FIG. 58B illustrates an example of a cross-sectional configuration of the seating 5. The first configuration of the seating 5 is an example in which the electric conductor 58 is produced previously.

As illustrated in FIGS. 58A and 58B, the imaging device 1 includes the seating 5. The seating 5 includes the curved housing section 50. The curved surface 50C of the curved housing section 50 is formed along an image-forming surface of an unillustrated module lens.

According to the imaging device 1 configured as described above, it is possible to reduce a corresponding load of image plane distortion in designing the module lens. In addition, it is possible to achieve a reduction in the number of lenses of the module lens, a reduction in the height of the module lens, higher resolution of the module lens, and the like.

In addition, the curved housing section 50 of the seating 5 may be formed in a curved shape in which the normal line of the curved surface 50C coincides with respect to the CRA of the module lens.

In addition, according to the seating 5 having such a shape, even in the case of high image height, a principal light beam is incident on the solid-state imaging element 2 vertically, thus making it possible to effectively suppress sensitivity loss due to vignetting in a pixel of the solid-state imaging element 2 and degradation in image quality such as oblique light color mixture.

Further, the imaging device 1 may be provided with the infrared cut filter 215 (see FIG. 22) formed in a curved shape in the same manner, on the side of the light-receiving surface 2A of the solid-state imaging element 2 fixed in a curved shape to the curved housing section 50 of the seating 5. This eliminates dependence on image height for an optical path difference in the infrared cut filter 215, thus making it possible to effectively suppress or prevent color shading.

In the imaging device 1, the solid-state imaging element 2 needs to be fixed to the curved housing section 50 of the seating 5 without causing a crack. In accordance with the physical principle, a thinner Si substrate that forms the base of the solid-state imaging element 2 is curved more easily. However, when handling the solid-state imaging element 2 as a sample, the possibility of the solid-state imaging element 2 being cracked is high.

For this reason, in reality, the thickness of the Si substrate is set to a range of 10 μm or more and 50 μm or less. Further, the thickness of the Si substrate is preferably set to a range of 15 μm or more and 35 μm or less.

### (2) Material of Seating 5

The seating 5 used for the curved mounting is formed by a material for which a thermal load in a mounting process and a thermal variation in a market environment are taken into consideration. In other words, the seating 5 is formed by a material that enables thermal expansion coefficients to be aligned as much as possible not to cause a stress due to a temperature change on the solid-state imaging element 2.

For example, when the Si substrate is used for the solid-state imaging element 2, the seating 5 is formed by Si. Si is optimum in that Si minimizes a thermal stress. In a case where Si is not used, it may be possible to form the seating 5 using a material having a thermal expansion coefficient close to the thermal expansion coefficient of Si of 4.15×10⁻⁶/°C.

In addition, in selecting the material of the seating 5, easiness in working, material cost, working cost, seating weight, rigidity, seating thinning, and the like are taken into consideration. Specific examples of the practically available material of the seating 5 include an inorganic insulator, a semiconductor material, a metal material, a resin material, and a ceramic material. In the imaging device 1 according to the third embodiment, the electric conductor 58 is disposed, and thus the seating 5 is preferably formed by an insulating material.

The semiconductor material includes C, SiC, and the like.

It may be possible to use, as the metal material, one or more metals selected from Al, Cu, brass, and Ti, or an alloy including one or more metals. The metal material is excellent in heat dissipation.

The resin material includes acrylic, polystyrene, polycarbonate, polypropylene, and the like. The resin material is excellent in cost reduction and weight reduction.

The ceramic material includes Al₂O₃, and the like. The ceramic material requires high cost, but is excellent in durability, heat dissipation, and the like.

### (3) Overall Configuration of Curved Housing Section 50

In the seating 5, the structure of the front surface of the curved housing section 50 is important. For example, the presence of a protrusion on the curved surface of the curved housing section 50 causes stress concentration to the solid-state imaging element 2 with the protrusion as an origin, thus causing the solid-state imaging element 2 to be easily damaged.

Even if the solid-state imaging element 2 is not damaged, the curved shape of the solid-state imaging element 2 is deformed due to the protrusion, and a deviation occurs on the image-forming surface of the module lens by an amount of the deformation, thus causing the resolution to be degraded.

Accordingly, the front surface of the curved shape of the curved housing section 50 is formed into a smooth surface where no protrusion is present.

The smooth surface may be formed using polishing working, grinding working, polishing buff working, wheel working, electrochemical polishing working, or the like. The front surface of a region of the curved housing section 50 in contact with the solid-state imaging element 2 has a maximum roughness/height of at least 1 μm or less. Preferably, the maximum roughness/height is 0.5 μm or less; more preferably, the maximum roughness/height is 0.1 μm or less.

Here, the maximum height/roughness is based on the definitions specified in the Japanese Industrial standard or JIS B0601:2013.

### (4) Configuration of Ventilation Section 53

The seating 5 includes, in the curved housing section 50, the ventilation section 53 penetrating from the curved surface 50C to the side of the back surface 50B opposed to the curved surface. The ventilation section 53 is able to discharge a gas to the outside of the seating 5 from the inside of space closed by the solid-state imaging element 2, the film 3 (see FIG. 22), and the curved housing section 50 of the seating 5, when the solid-state imaging element 2 is curved by a pressure difference between gases such as air. That is, the ventilation section 53 is used when mounting the solid-state imaging element 2 and the film 3 in a curved shape on the seating 5 using a pressure difference.

The ventilation section 53 is formed by a through-hole. The embedded member 54 (see (A) and (B) of FIG. 13) such as a porous material may be embedded in the ventilation section 53.

The electric conductor 58 is disposed in the ventilation section 53 that serves also as a hole array. The one end of the electric conductor 58 is electrically coupled to the element terminal BP of the solid-state imaging element 2, and the other end of the electric conductor 58 is electrically coupled to the mounting terminal 701 of the mounting substrate 700 (see FIG. 22).

The electric conductor 58 is formed by Cu, for example. Cu is formed as a film by plating processing, for example.

In addition, the electric conductor 58 may be formed by selective pasting of a high-melting-point material such as Sn, Ag, Cu, or Pb. At this time, one of the side of the curved surface 50C or the side of the back surface 50B of the seating 5 is clogged with a provisional material to prevent leakage of the electric conductor 58 from the ventilation section 53, and then the provisional material is removed.

In addition, a flat provisional material including a metal at a position corresponding to the ventilation section 53 may be formed on the back surface 50B of the seating 5, and the electric conductor 58 may be selectively formed for the metal. For example, Cu by means of plating processing is used for the electric conductor 58.

The first configuration of the seating 5 concerns the electric conductor.

### (5) Second Configuration of Seating 5

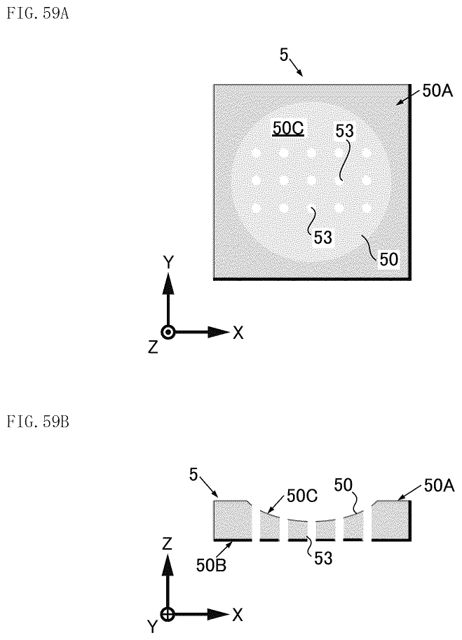

FIG. 59A illustrates an example of a planar configuration of the seating 5 of the imaging device 1 according to the third embodiment. FIG. 59B illustrates an example of a cross-sectional configuration of the seating 5. The second configuration of the seating 5 is an example in which the electric conductor 58 is produced afterward.

As illustrated in FIGS. 59A and 59B, the seating 5 includes the ventilation sections 53. Most of the ventilation sections 53 serve also as a hole array. In the manufacturing process, the electric conductor 58 is embedded in the ventilation section 53.

Components other than those described above are the same as or substantially the same as the components of the first configuration of the seating 5.

### (6) Third Configuration and Manufacturing Method of Seating 5

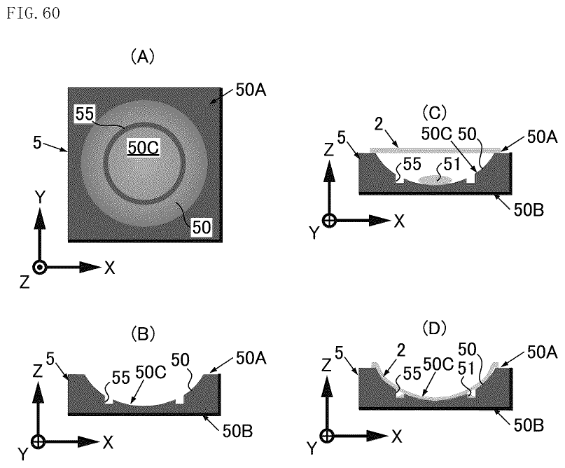

FIG. 60 illustrates an example of a step describing a manufacturing method in which the solid-state imaging element 2 is mounted on the curved housing section 50 of the seating 5. (A) of FIG. 60 illustrates an example of a planar configuration of the seating 5 before mounting. (B) of FIG. 60 illustrates an example of a cross-sectional configuration of the seating 5 before the mounting. (C) of FIG. 60 illustrates an example of a cross-sectional configuration at the time when the solid-state imaging element 2 is placed on the curved housing section 50 of the seating 5. (D) of FIG. 60 illustrates an example of a cross-sectional configuration of the imaging device 1 in which the solid-state imaging element 2 is mounted on the curved housing section 50 of the seating 5.

First, as illustrated in (A) and (B) of FIG. 60, the seating 5 is formed. The seating 5 includes the curved housing section 50. The pocket 55 is formed around a middle part close to the center position of the front surface 50A of the seating 5. In a side view, the pocket 55 is formed in a groove shape that is further recessed from the front surface of the curved housing section 50 in the incident direction of the incident light L. In addition, here, the pocket 55 is formed in a circular ring shape in a plan view, although not particularly limited thereto. The pocket 55 takes in an excess of the glue 51 formed in the curved housing section 50 to effectively suppress or prevent an overflow of the glue 51 from between the curved housing section 50 and the solid-state imaging element 2.

Meanwhile, the solid-state imaging element 2 is formed.

As illustrated in (C) of FIG. 60, the glue 51 is formed in the curved housing section 50 of the seating 5, and, further, the solid-state imaging element 2 is placed on the curved housing section 50.

For example, the above-described pressure difference is generated, and the solid-state imaging element 2 is formed in a curved shape along the curved shape of the curved housing section 50, as illustrated in (D) of FIG. 60. The glue 51 allows the solid-state imaging element 2 to be adhered to the inside of the curved housing section 50 to form the imaging device 1 in which the solid-state imaging element 2 is mounted on the seating 5.

It is to be noted that the variation of the position at which the pocket 55 is disposed is as described above (see FIG. 15).

### (7) Fourth Configuration of Seating 5

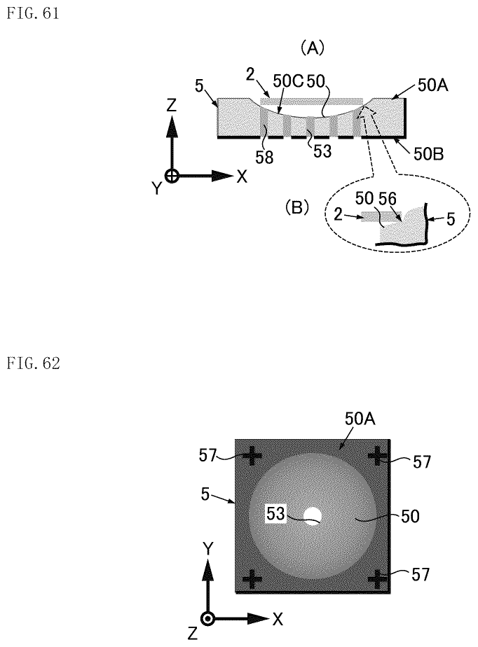

FIG. 61 is a diagram describing a fourth configuration of the seating 5. (A) of FIG. 61 illustrates an example of a cross-sectional configuration of the seating 5 and the solid-state imaging element 2 before mounting. (B) of FIG. 61 illustrates an example of an enlarged cross-sectional configuration of a main part of the seating 5 and the solid-state imaging element 2.

As illustrated in (A) and (B) of FIG. 61, the stepped part 56 is formed in the curved housing section 50 of the seating 5. The stepped part 56 is formed as a positioning guide that abuts a peripheral end of the solid-state imaging element 2 placed in the curved housing section 50 to perform positioning of the solid-state imaging element 2 with respect to the curved housing section 50.

According to the seating 5 configured as described above, it is possible to perform positioning of the solid-state imaging element 2 on the curved housing section 50 easily and accurately by using the stepped part 56.

### (8) Fifth Configuration of Seating 5

FIG. 62 illustrates an example of a planar configuration describing a fifth configuration of the seating 5.

As illustrated in FIG. 62, the mark 57 is formed in a peripheral part of the front surface 50A of the seating 5. The mark 57 is formed as an alignment mark to perform positioning of the curved housing section 50 of the seating 5 and the solid-state imaging element 2. Positioning of the mark 57 is performed with respect to an outline shape of the solid-state imaging element 2, for example.

According to the seating 5 configured as described above, the use of the mark 57 makes it possible to perform positioning of the solid-state imaging element 2 on the curved housing section 50 easily and accurately.

It is to be noted that, in the seating 5, the ventilation section 53, the pocket 55, or the stepped part 56 described above to be brought into contact with the solid-state imaging element 2 has a rounding shape in which corner portions have roundness. It is possible, in a region having the rounding shape, to effectively suppress or prevent stress concentration that occurs in the solid-state imaging element 2 formed in a curved shape and subjected to the stress. [Configuration of Element Terminal BP, Electric Conductor 58, and Mounting Terminal 701] Next, respective coupling configurations of the element terminal BP of the solid-state imaging element 2, the electric conductor 58 of the seating 5, and the mounting terminal 701 of the mounting substrate 700 are as follows.

### (1) First Coupling Configuration

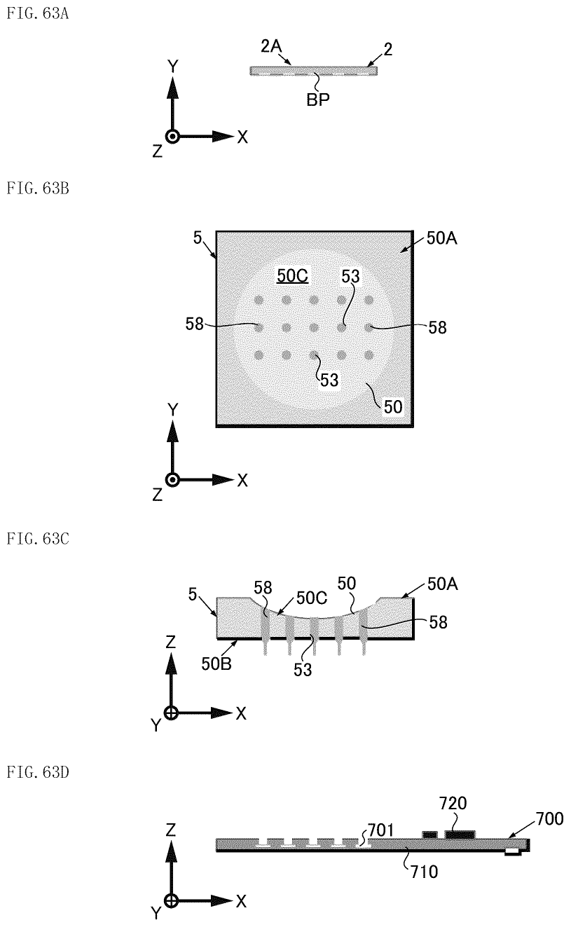

FIGS. 63A to 63D illustrate an example of a first coupling configuration of the imaging device 1. FIG. 63A illustrates an example of a cross-sectional configuration of the solid-state imaging element 2. FIG. 63B illustrates an example of a planar configuration of the seating 5. FIG. 63C illustrates an example of a cross-sectional configuration of the seating 5. FIG. 63D illustrates an example of a cross-sectional configuration of the mounting substrate 700.

As illustrated in FIG. 63A, in the solid-state imaging element 2 of the imaging device 1, the element terminal BP is formed in a flat shape.

As illustrated in FIGS. 63B and 63C, one end of the electric conductor 28 of the seating 5 corresponds to the element terminal BP, and is formed in a flat shape. Meanwhile, another end of the electric conductor 28 is protruded from the back surface 50B of the seating 5, and is formed in a pin shape (convex shape).

As illustrated in FIG. 63D, the mounting terminal 701 of the mounting substrate 700 is recessed from the surface of the base material 710, and is formed in a socket shape (concave shape) into which the other end of the electric conductor 28 is inserted.

The pin shape may be a hanging bell shape, an elongated rod shape for use in a pin grid array (PGA: Pin Grid Array), or a plug-in shape for use in a dual in line (DIL: Dual In Line). As for the socket shape, it is sufficient for the base material 710 to include therein an electrode and to have an opening, on the surface of the base material 710, into which the other end of the electric conductor 28 is inserted.

According to the imaging device 1 configured as described above, it is possible to perform electric coupling and positioning easily, quickly, and with high accuracy between the mounting terminal 701 and the electric conductor 28. That is, it is possible to provide the imaging device 1 that makes it possible to achieve a mounting operation easily, quickly, and with high accuracy.

### (2) Second Coupling Configuration

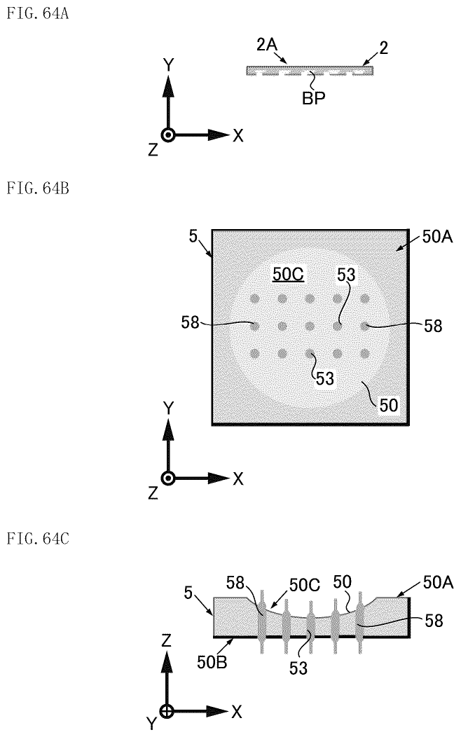

FIGS. 64A to 64C illustrate an example of a second coupling configuration of the imaging device 1. FIG. 64A illustrates an example of a cross-sectional configuration of the solid-state imaging element 2. FIG. 64B illustrates an example of a planar configuration of the seating 5. FIG. 64C illustrates an example of a cross-sectional configuration of the seating 5. The cross-sectional configuration of the mounting substrate 700 is the same as the cross-sectional configuration of the mounting substrate 700 illustrated in FIG. 63D.

As illustrated in FIG. 64A, in the solid-state imaging element 2 of the imaging device 1, the element terminal BP is formed in a socket shape.

As illustrated in FIGS. 64B and 64C, one end of the electric conductor 28 of the seating 5 corresponds to the element terminal BP, and is protruded from the curved surface 50C and is formed in a pin shape. Meanwhile, another end of the electric conductor 28 is protruded from the back surface 50B of the seating 5, and is formed in a pin shape.

As illustrated in FIG. 63D mentioned above, the mounting terminal 701 of the mounting substrate 700 is formed in a socket shape.

According to the imaging device 1 configured as described above, it is possible to perform, easily, quickly, and with high accuracy, electric coupling and positioning between the element terminal BP and the electric conductor 28 as well as electric coupling and positioning between the mounting terminal 701 and the electric conductor 28.

### (3) Third Coupling Configuration

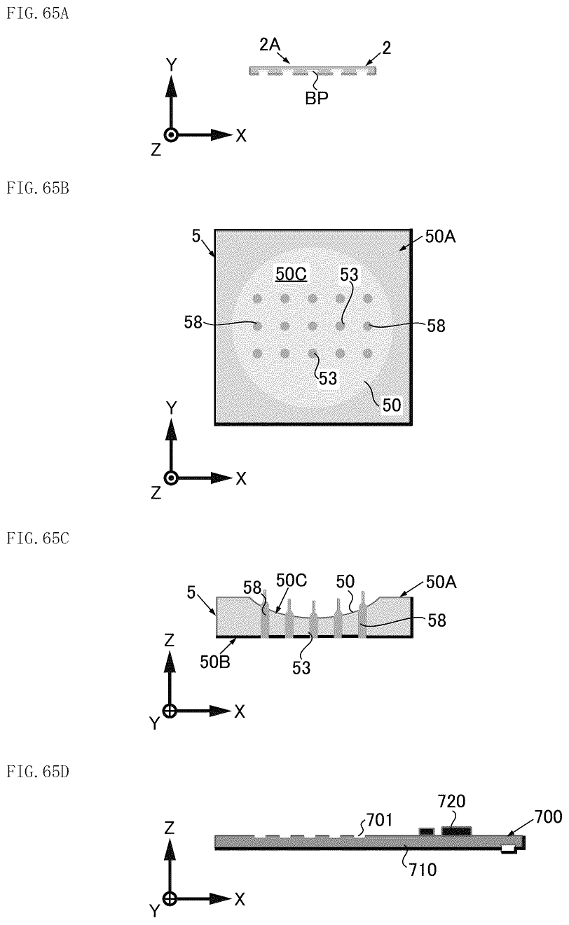

FIGS. 65A to 65D illustrate an example of a third coupling configuration of the imaging device 1. FIG. 65A illustrates an example of a cross-sectional configuration of the solid-state imaging element 2. FIG. 65B illustrates an example of a planar configuration of the seating 5. FIG. 65C illustrates an example of a cross-sectional configuration of the seating 5. FIG. 65D illustrates an example of a cross-sectional configuration of the mounting substrate 700.

As illustrated in FIG. 65A, in the solid-state imaging element 2 of the imaging device 1, the element terminal BP is formed in a socket shape.

As illustrated in FIGS. 65B and 65C, one end of the electric conductor 28 of the seating 5 corresponds to the element terminal BP, and is protruded from the curved surface 50C and is formed in a flat shape. Meanwhile, another end of the electric conductor 28 is formed in a flat shape.

As illustrated in FIG. 65D, the mounting terminal 701 of the mounting substrate 700 is formed in a flat shape.

According to the imaging device 1 configured as described above, it is possible to perform electric coupling and positioning easily, quickly, and with high accuracy between the element terminal BP and the electric conductor 28.

### (4) Fourth Coupling Configuration

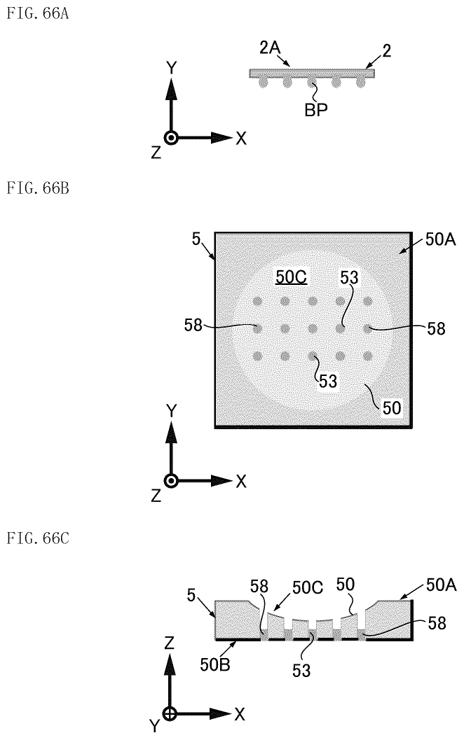

FIGS. 66A to 66C illustrate an example of a second coupling configuration of the imaging device 1. FIG. 66A illustrates an example of a cross-sectional configuration of the solid-state imaging element 2. FIG. 66B illustrates an example of a planar configuration of the seating 5. FIG. 66C illustrates an example of a cross-sectional configuration of the seating 5. The cross-sectional configuration of the mounting substrate 700 is the same as the cross-sectional configuration of the mounting substrate 700 illustrated in FIG. 65D.

As illustrated in FIG. 66A, in the solid-state imaging element 2 of the imaging device 1, the element terminal BP is formed in a pin shape.

As illustrated in FIGS. 66B and 66C, one end of the electric conductor 28 of the seating 5 corresponds to the element terminal BP, and is recessed from the curved surface 50C to the side of the back surface 50B and is formed in a socket shape. Meanwhile, another end of the electric conductor 28 is formed in a flat shape.

As illustrated in FIG. 63D mentioned above, the mounting terminal 701 of the mounting substrate 700 is formed in a flat shape.

According to the imaging device 1 configured as described above, it is possible to perform electric coupling and positioning easily, quickly, and with high accuracy between the element terminal BP and the electric conductor 28.

### (5) Fifth Coupling Configuration

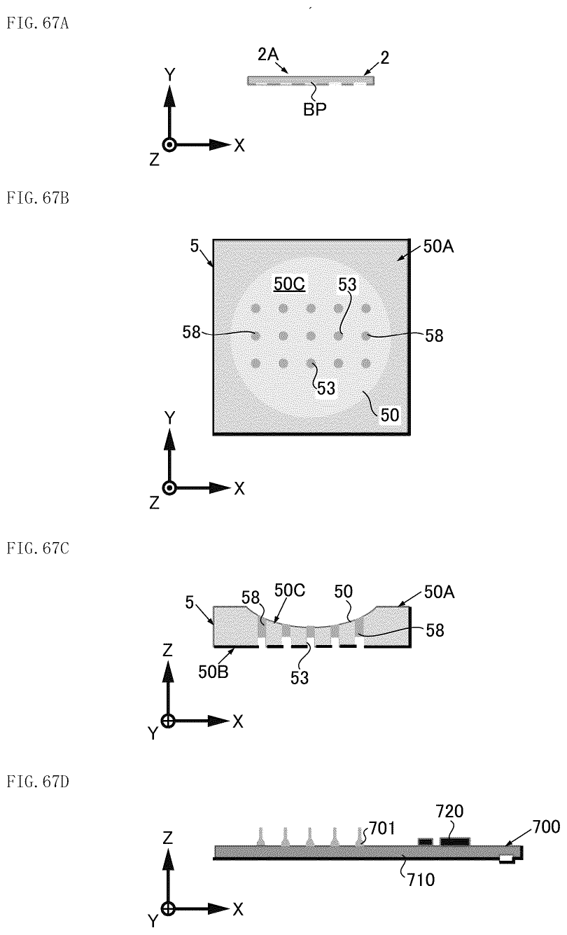

FIGS. 67A to 67D illustrate an example of a fifth coupling configuration of the imaging device 1. FIG. 67A illustrates an example of a cross-sectional configuration of the solid-state imaging element 2. FIG. 67B illustrates an example of a planar configuration of the seating 5. FIG. 67C illustrates an example of a cross-sectional configuration of the seating 5. FIG. 67D illustrates an example of a cross-sectional configuration of the mounting substrate 700.

As illustrated in FIG. 67A, in the solid-state imaging element 2 of the imaging device 1, the element terminal BP is formed in a flat shape.

As illustrated in FIGS. 67B and 67C, one end of the electric conductor 28 of the seating 5 corresponds to the element terminal BP, and is formed in a flat shape. Meanwhile, another end of the electric conductor 28 is recessed from the back surface 50B of the seating 5 to the side of the curved surface 50C, and is formed in a socket shape.

As illustrated in FIG. 67D, the mounting terminal 701 of the mounting substrate 700 is protruded from the surface of the base material 710, and is formed in a pin shape that allows insertion into the other end of the electric conductor 28.

According to the imaging device 1 configured as described above, it is possible to perform electric coupling and positioning easily, quickly, and with high accuracy between the mounting terminal 701 and the electric conductor 28.

### (6) Sixth Coupling Configuration

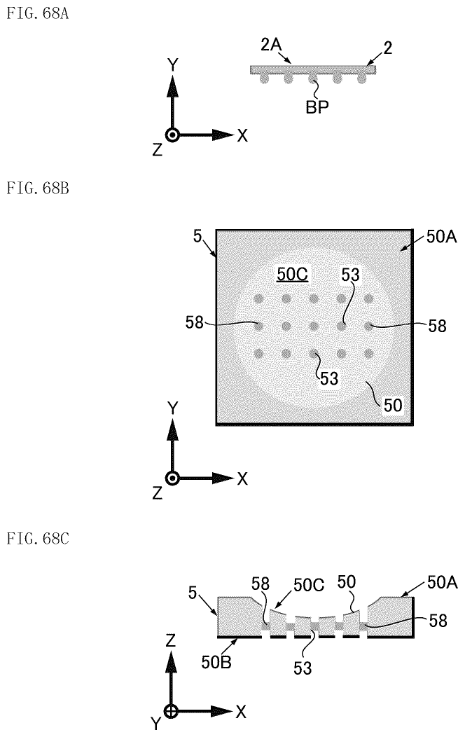

FIGS. 68A to 68C illustrate an example of a second coupling configuration of the imaging device 1. FIG. 68A illustrates an example of a cross-sectional configuration of the solid-state imaging element 2. FIG. 68B illustrates an example of a planar configuration of the seating 5. FIG. 68C illustrates an example of a cross-sectional configuration of the seating 5. The cross-sectional configuration of the mounting substrate 700 is the same as the cross-sectional configuration of the mounting substrate 700 illustrated in FIG. 67D.

As illustrated in FIG. 68A, in the solid-state imaging element 2 of the imaging device 1, the element terminal BP is formed in a pin shape.

As illustrated in FIGS. 68B and 68C, one end of the electric conductor 28 of the seating 5 corresponds to the element terminal BP, and is recessed from the curved surface 50C to the side of the back surface 50B and is formed in a socket shape. Meanwhile, another end of the electric conductor 28 is recessed from the back surface 50B to the curved surface 50C, and is formed in a socket shape.

As illustrated in FIG. 67D mentioned above, the mounting terminal 701 of the mounting substrate 700 is formed in a pin shape.

According to the imaging device 1 configured as described above, it is possible to perform, easily, quickly, and with high accuracy, electric coupling and positioning between the element terminal BP and the electric conductor 28 as well as electric coupling and positioning between the electric conductor 28 and the mounting terminal 701.

### <4. Fourth Embodiment>

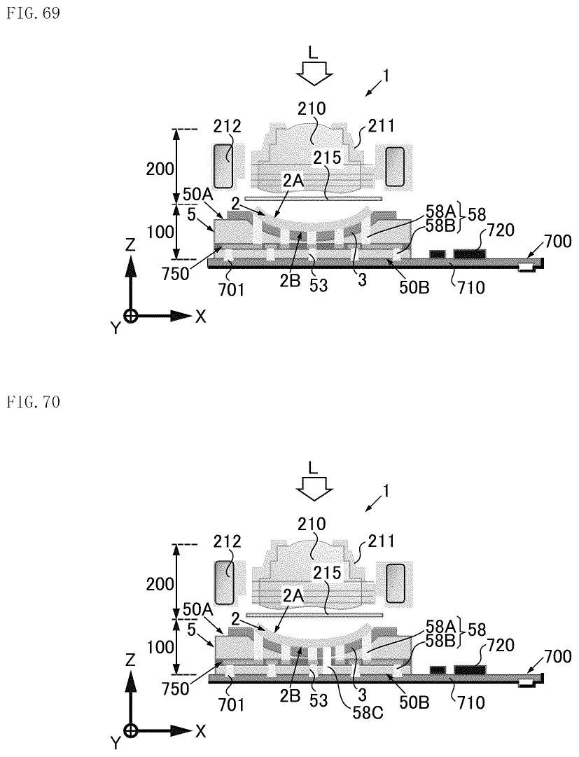

Description is given, with reference to FIGS. 69 and 70, of the imaging device 1 and a method of manufacturing the imaging device 1 according to the fourth embodiment of the present disclosure.

### [First Configuration of Imaging Device 1]

FIG. 69 illustrates an example of a cross-sectional configuration of the imaging device 1 according to the fourth embodiment. The fourth embodiment is a practical application example of the imaging device 1 according to the third embodiment.

As illustrated in FIG. 69, the imaging device 1 includes the element section 100 and the optical section 200, in the same manner as the imaging device 1 according to the third embodiment. Further, the element section 100 includes the solid-state imaging element 2, the film 3, the seating 5, an intermediate wiring substrate 750 mounted on the seating 5, and the mounting substrate 700 to be mounted with the seating 5.

### (1) Configuration of Element Section 100

The solid-state imaging element 2 is configured by, for example, the CSP structure that pulls out the element terminals BP from directly under the back surface. The BGA structure or the Cu-LGA structure is adopted for the solid-state imaging element 2.

According to the imaging device 1 configured as described above, the coupling using the wire 9 (see FIG. 8) is not used. This makes it possible to reduce the size of the solid-state imaging element 2, because the wire 9 is not led around to the outside of the solid-state imaging element 2.

In addition, a wiring length is reduced in coupling the solid-state imaging element 2 and the mounting substrate 700 to each other, thus making it possible to achieve a higher operation speed of the imaging device 1.

The infrared cut filter 215 (see FIG. 22) is disposed on the side of the light-receiving surface 2A of the solid-state imaging element 2. As the infrared cut filter 215, there is adopted an absorption type, a multilayer film type in which dielectric films of different refractive indexes are stacked, or a hybrid type in which both of the absorption type and the multilayer film type are combined.

This eliminates dependence on image height for an optical path difference in the infrared cut filter 215, thus making it possible to effectively suppress or prevent color shading.

In addition, it is possible to reduce the number of members of the infrared cut filter on a side of the module lens.

In addition, the solid-state imaging element 2 having the CSP structure described above may be a stacked solid-state imaging element to which a logic substrate is attached. In this case, the thickness of the solid-state imaging element 2 is increased; however, it is possible to reduce an area of a peripheral circuit disposed around the light-receiving surface 2A in the solid-state imaging element 2.

According to the solid-state imaging element 2 configured as described above, it is possible to increase the number of acquisitions from semiconductor wafers in the manufacturing process. In addition, it is possible to allocate a large-scale circuit with added value to the side of the logic substrate.

### (2) Configuration of Intermediate Wiring Substrate 750

The intermediate wiring substrate 750 is disposed at an intermediate part of the seating 5 in a thickness direction (arrow-Z direction). The intermediate wiring substrate 750 is formed by, for example, one or more base materials selected from an organic resin substrate, a ceramic substrate, and a glass substrate for use in a liquid crystal display. The intermediate wiring substrate 750 is provided with unillustrated monolayer or multilayer wiring.

The solid-state imaging element 2 is electrically coupled to the mounting substrate 700 through the intermediate wiring substrate 750. To be described in detail, the element terminal BP of the solid-state imaging element 2 is electrically coupled to the intermediate wiring substrate 750 through an electric conductor 28A of the electric conductor 28 of the seating 5. In addition, the intermediate wiring substrate 750 is electrically coupled to the mounting terminal 701 of the mounting substrate 700 through an electric conductor 28B of the electric conductor 28 of the seating 5.

The electric conductor 28 is formed by utilizing the manufacturing method of the imaging device 1 according to the foregoing third embodiment. The intermediate wiring substrate 750 is bonded to the seating 5 using a glue, and is electrically coupled to the electric conductor 28.

Here, as the glue, one or more resin glues selected from an epoxy-based resin, an acrylic-based resin, and a cyan-based resin are used. As the glue, a UV-cured type, a temperature-cured type, a time-cured type, or the like is usable, and no particular limitation is made on the cured type. In a case where the UV-cured type is adopted as the glue, the seating 5 is formed by a material

### That Transmits Uv.

In addition, the electric conductor 28 may be formed by pasting of a high-melting-point material. Sn, Ag, Cu, Pb or the like is usable as the high-melting-point material.

In addition, the electric conductor 28 may be formed on a disposed metal. As the electric conductor 28, Cu formed on the metal by plating processing is used.

In addition, the electric conductor 28 may be formed by an electrically-conductive resin. Further, an ultrasonic vibration method or a thermocompression bonding method is used for the electric coupling.

In addition, it may be possible to adopt, for the coupling between the intermediate wiring substrate 750 and the electric conductor 28, the first to sixth coupling configurations described for the imaging device 1 according to the foregoing third embodiment. According to the adoption thereof, it is possible to achieve the mounting operation easily, quickly, and with high accuracy.

Further, using an underfill material for bonding between the seating 5 and the intermediate wiring substrate 750 enables the bonding to be firmly performed.

### [Workings and Effects]

According to the imaging device 1 configured as described above, the intermediate wiring substrate 750 is disposed in the seating 5, thus making it possible to enhance the degree of freedom in the design of a terminal layout (changing connections, etc.).

In addition, allocating a portion of the mounting substrate 700 to the intermediate wiring substrate 750 of the seating 5 makes it possible to reduce a circuit size of the mounting substrate 700. It is therefore possible to effectively reduce the manufacturing cost of the imaging device 1.

In addition, the mounting substrate 700 and the intermediate wiring substrate 750 are configured to have a two-tier substrate structure, thus making it possible to achieve a reduction in size of the imaging device 1 as well as a reduction in space.

In addition, it is possible to allocate a logic circuit of the solid-state imaging element 2 to the intermediate wiring substrate 750, thus making it possible to achieve a reduction in the circuit size.

### [Second Configuration of Imaging Device 1]

FIG. 70 illustrates an example of a cross-sectional configuration of the imaging device 1 according to the fourth embodiment.

As illustrated in FIG. 70, in the imaging device 1 according to the first configuration, the imaging device 1 is provided with an electric conductor 28C that penetrates the intermediate wiring substrate 750 in the seating 5.

Components other than those described above are the same as or substantially the same as the components of the imaging device 1 according to the first configuration.

It is to be noted that, in the imaging device 1, the intermediate wiring substrate 750 may be disposed between the seating 5 and the mounting substrate 700.

### <5. Fifth Embodiment>

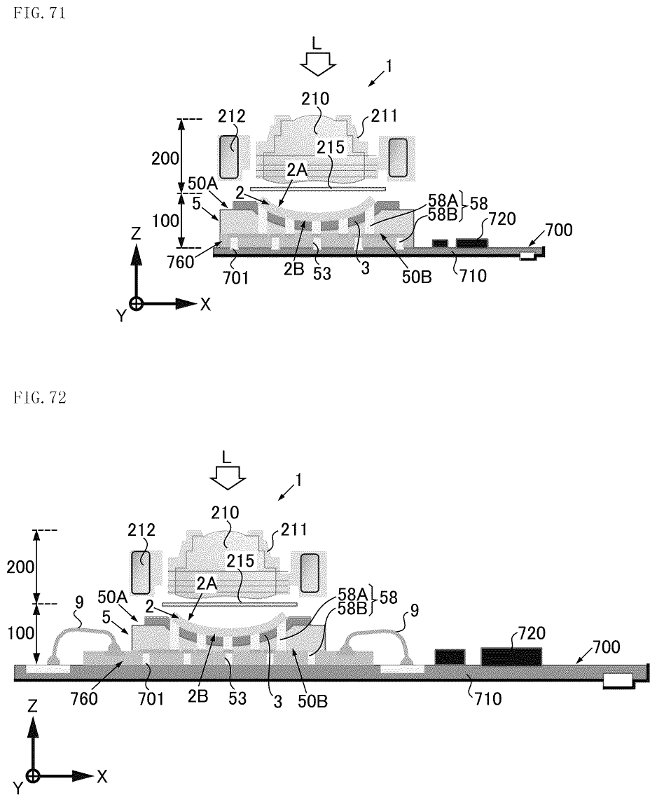

Description is given, with reference to FIGS. 71 and 72, of the imaging device 1 and a method of manufacturing the imaging device 1 according to the fifth embodiment of the present disclosure.

### [First Configuration of Imaging Device 1]

FIG. 71 illustrates an example of a cross-sectional configuration of the imaging device 1 according to the fifth embodiment. The fourth embodiment is a practical application example of the imaging device 1 according to the third embodiment.

As illustrated in FIG. 71, the imaging device 1 includes the element section 100 and the optical section 200, in the same manner as the imaging device 1 according to the third embodiment. Further, the element section 100 includes the solid-state imaging element 2, the film 3, the seating 5, the mounting substrate 700, and a logic chip 760 disposed between the seating 5 and the mounting substrate 700.

### (1) Configuration of Element Section 100

The solid-state imaging element 2 is configured by, for example, the CSP structure that pulls out the element terminals BP from directly under the back surface. The BGA structure or the Cu-LGA structure is adopted for the solid-state imaging element 2.

According to the imaging device 1 configured as described above, the coupling using the wire 9 (see FIG. 8) is not used. This makes it possible to reduce the size of the solid-state imaging element 2, because the wire 9 is not led around to the outside of the solid-state imaging element 2.

In addition, a wiring length is reduced in coupling the solid-state imaging element 2 and the mounting substrate 700 to each other, thus making it possible to achieve a higher operation speed of the imaging device 1.

The imaging device 1 includes the seating 5 that includes the curved housing section 50. The curved surface 50C of the curved housing section 50 is formed along an image-forming surface of an unillustrated module lens.

According to the imaging device 1 configured as described above, it is possible to reduce a corresponding load of image plane distortion in designing the module lens. In addition, it is possible to achieve a reduction in the number of lenses of the module lens, a reduction in the height of the module lens, higher resolution of the module lens, and the like.

In addition, the curved housing section 50 of the seating 5 may be formed in a curved shape in which the normal line of the curved surface 50C coincides with respect to the CRA of the module lens.

In addition, according to the seating 5 having such a shape, even in the case of high image height, a principal light beam is incident on the solid-state imaging element 2 vertically, thus making it possible to effectively suppress sensitivity loss due to vignetting in a pixel of the solid-state imaging element 2 and degradation in image quality such as oblique light color mixture.

The seating 5 includes, in the curved housing section 50, the ventilation section 53 penetrating from the curved surface 50C to the side of the back surface 50B opposed to the curved surface 50C. The ventilation section 53 is able to discharge a gas to the outside of the seating 5 from the inside of space closed by the solid-state imaging element 2, the film 3, and the curved housing section 50 of the seating 5, when the solid-state imaging element 2 is curved by a pressure difference between gases such as air.

The ventilation section 53 is formed by a through-hole. The embedded member 54 (see (A) and (B) of FIG. 13) such as a porous material may be embedded in the ventilation section 53.

In addition, the ventilation section 53 of the seating 5 is used, for example, as a gas vent in the manufacturing process, and a plurality of ventilation sections 53 is arrayed and serves also as a hole array. The electric conductor 58 is embedded in the ventilation section 53 that serves also as the hole array. One end of the electric conductor 58 is electrically coupled to the solid-state imaging element 2, and another end of the electric conductor 58 is electrically coupled to the mounting substrate 700.

### (2) Configuration of Logic Chip 760

The logic chip 760 is disposed, on the side of the back surface 50B of the seating 5, between the seating 5 and the mounting substrate 700. A structure similar to the BGA structure or the Cu-LGA structure is adopted for a coupling structure between the seating 5 and the logic chip 760. An ultrasonic vibration method or a thermocompression bonding method is used for the coupling. In addition, using a plasma bonding technique enables firm coupling.

A structure similar to the BGA structure or the Cu-LGA structure is adopted for a coupling structure between the logic chip 760 and the mounting substrate 700. An ultrasonic vibration method or a thermocompression bonding method is used for the coupling. In addition, using a plasma bonding technique enables firm coupling.

The mounting substrate 700 is mounted with a semiconductor component, e.g., an LSI (Large Scale Integration) such as a capacitor, a resistor, and an auto focus driver to drive the actuator 212, and with the electric element 720 such as a connector to output an imaging signal from the solid-state imaging element 2 to an external device.

### [Workings and Effects]

According to the imaging device 1 configured as described above, providing the logic chip 760 makes it is possible to reduce the area of the peripheral circuit disposed around the light-receiving surface 2A in the solid-state imaging element 2, without increasing the thickness of the solid-state imaging element 2. It is therefore possible to increase the number of acquisitions of the solid-state imaging element 2 from semiconductor wafers in the manufacturing process. In addition, it is possible to allocate a large-scale circuit with added value to a side of the logic chip 760.

### [Second Configuration of Imaging Device 1]

FIG. 72 illustrates an example of a cross-sectional configuration of the imaging device 1 according to the fifth embodiment.

As illustrated in FIG. 72, in the imaging device 1 according to the first configuration, the imaging device 1 is provided with the logic chip 760 and the mounting substrate 700 which are electrically coupled to each other through the wire 9.

Components other than those described above are the same as or substantially the same as the components of the imaging device 1 according to the first configuration.

It is to be noted that, in the present disclosure, the imaging device 1 according to the first configuration and the imaging device 1 according to the second configuration may be combined with each other.

### <6. Other Embodiments>

The present disclosure is not limited to the foregoing embodiments. For example, in the present disclosure, two or more of the respective examples described for the imaging devices and the methods of manufacturing the imaging devices according to the foregoing embodiments may be combined.

An imaging device according to a first embodiment of the present disclosure includes a solid-state imaging element and a seating. The solid-state imaging element includes, on a base, a light-receiving surface on which a plurality of pixels is arranged in a two-dimensional array. The pixels each include a photoelectric conversion region that converts incident light into an electric signal. The seating is provided with a curved surface recessed in an incident direction of incident light. The seating includes a curved housing section that houses the solid-state imaging element. In this imaging device, the light-receiving surface and the curved surface are caused to face each other, and the solid-state imaging element is disposed in a curved state on the curved housing section.

According to the imaging device configured as described above, the light-receiving surface of the solid-state imaging element is not damaged.

In an imaging device according to a second embodiment of the present disclosure, a film is disposed between the solid-state imaging element and the curved housing section, in the imaging device according to the first embodiment.

According to the imaging device configured as described above, the light-receiving surface of the solid-state imaging element and the film are not brought into contact with each other.

An imaging device according to a third embodiment of the present disclosure includes a mounting substrate to be mounted with the seating on a side of a back surface opposed to the curved surface, in the imaging device according to the first embodiment, and the seating includes an electric conductor having one end being electrically coupled to the solid-state imaging element in the curved housing section, and another end being electrically coupled to the mounting substrate. According to the imaging device configured as described above, it is possible to effectively reduce the manufacturing cost.

An imaging device according to a fourth embodiment of the present disclosure further includes, between the solid-state imaging element and the curved housing section of the seating, a wiring substrate including a wiring layer and being formed in a curved shape along the curved surface of the curved housing section, in the imaging device according to the first embodiment. According to the imaging device configured as described above, it is possible to effectively reduce the manufacturing cost.

A method of manufacturing an imaging device according to a fifth embodiment of the present disclosure includes: forming a solid-state imaging element including, on a base, a light-receiving surface on which a plurality of pixels is arranged in a two-dimensional array, the pixels each including a photoelectric conversion region that converts incident light into an electric signal; forming a seating provided with a curved surface recessed in an incident direction of incident light, the seating including a curved housing section that houses the solid-state imaging element; causing the light-receiving surface and the curved surface to face each other; and forming the solid-state imaging element in a curved state on the curved housing section, with a film being interposed between the solid-state imaging element and the curved housing section.

According to the method of manufacturing the imaging device configured as described above, the light-receiving surface of the solid-state imaging element is not damaged.

### <Configuration of Present Disclosure>

The present disclosure includes the following configurations. Providing the following configurations makes it possible to provide an imaging device that does not damage a light-receiving surface of a solid-state imaging element and a method of manufacturing the imaging device.

(1)

An imaging device including:
a solid-state imaging element including, on a base, a light-receiving surface on which a plurality of pixels is arranged in a two-dimensional array, the pixels each including a photoelectric conversion region that converts incident light into an electric signal; and
a seating provided with a curved surface recessed in an incident direction of incident light, the seating including a curved housing section that houses the solid-state imaging element, in which
a back surface of the base opposed to the light-receiving surface and the curved surface are caused to face each other, and
the solid-state imaging element is disposed in a curved state on the curved housing section.
   (2)

The imaging device according to (1), in which a film is disposed between the solid-state imaging element and the curved housing section.

(3)

The imaging device according to (2), in which the film is softer than the solid-state imaging element.

(4)

The imaging device according to (2) or (3), in which a glue is formed on a surface of the film on a side of the solid-state imaging element and on a surface of the film on a side of the curved surface.

(5)

The imaging device according to any one of (1) to (4), in which the seating includes, in the curved housing section, a ventilation section that penetrates from the curved surface toward a side of a back surface opposed to the curved surface.

(6)

The imaging device according to any one of (1) to (4), including a mounting substrate to be mounted with the seating on the side of the back surface opposed to the curved surface, in which the seating includes an electric conductor having one end and another end, the one end being electrically coupled to the solid-state imaging element in the curved housing section, the other end being electrically coupled to the mounting substrate.

(7)

The imaging device according to (6), including a film disposed between the solid-state imaging element and the curved housing section, the film having an opening at a position corresponding to the electric conductor, the opening allowing for electrical coupling between the solid-state imaging element and the electric conductor.

(8)

The imaging device according to (7), including an element terminal disposed at a position corresponding to the opening of the film, on the back surface of the base opposed to the light-receiving surface of the solid-state imaging element, the element terminal allowing for electrical coupling between the solid-state imaging element and the electric conductor.

(9)

The imaging device according to (8), in which the element terminal is protruded from the surface of the film on the side of the curved surface.

(10)

The imaging device according to (8), in which
the electric conductor is protruded from the curved surface to a side of the film, and
the element terminal is recessed from the surface of the film on the side of the curved surface to the side of the solid-state imaging element.
   (11)

The imaging device according to (8), in which
the electric conductor is recessed from the curved surface to a side of the mounting substrate, and
the element terminal is protruded from the surface of the film on the side of the curved surface to the side of the curved surface.
   (12)

The imaging device according to (8), (10), or (11), in which
the mounting substrate includes a mounting terminal at a position corresponding to the electric conductor, the mounting terminal being electrically coupled to the electric conductor,
the electric conductor is protruded from the back surface of the seating to the side of the mounting substrate, and
the mounting terminal is recessed from a surface of the mounting substrate on a side of the seating to a side of a back surface of the mounting substrate.
   (13)

The imaging device according to (8), (10), or (11), in which
the mounting substrate includes a mounting terminal at a position corresponding to the electric conductor, the mounting terminal being electrically coupled to the electric conductor,
the electric conductor is recessed from the back surface of the seating to the side of the curved surface, and
the mounting terminal is protruded from a surface of the mounting substrate on a side of the seating to the side of the seating.
   (14)

The imaging device according to any one of (1) to (13), further including, between the solid-state imaging element and the curved housing section of the seating, a wiring substrate including a wiring layer and being formed in a curved shape along the curved surface of the curved housing section.

(15)

The imaging device according to (14), in which
the wring substrate has flexibility,
a portion of the wiring substrate is extended to a periphery of a side surface of the seating, and
a portion of the wiring substrate is mounted with an electric element.
   (16)

The imaging device according to (14) or (15), in which the wiring substrate includes a plurality of the wiring layers.

(17)

A method of manufacturing an imaging device, the method including:
forming a solid-state imaging element including, on a base, a light-receiving surface on which a plurality of pixels is arranged in a two-dimensional array, the pixels each including a photoelectric conversion region that converts incident light into an electric signal;
forming a seating provided with a curved surface recessed in an incident direction of incident light, the seating including a curved housing section that houses the solid-state imaging element;
causing a back surface of the base opposed to the light-receiving surface and the curved surface to face each other; and
forming the solid-state imaging element in a curved state on the curved housing section, with a film being interposed between the solid-state imaging element and the curved housing section.

The present application claims the benefit of U.S. Provisional Patent Application No. 63/456151 filed with the United States Patent and Trademark Office on Mar. 31, 2023, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging device, comprising:
a solid-state imaging element including, on a base, a light-receiving surface on which a plurality of pixels is arranged in a two-dimensional array, the pixels each including a photoelectric conversion region that converts incident light into an electric signal; and
a seating provided with a curved surface recessed in an incident direction of incident light, the seating including a curved housing section that houses the solid-state imaging element, wherein
a back surface of the base opposed to the light-receiving surface and the curved surface are caused to face each other, and
the solid-state imaging element is disposed in a curved state on the curved housing section.

2. The imaging device according to claim 1, wherein a film is disposed between the solid-state imaging element and the curved housing section.

3. The imaging device according to claim 2, wherein the film is softer than the solid-state imaging element.

4. The imaging device according to claim 2, wherein a glue is formed on a surface of the film on a side of the solid-state imaging element and on a surface of the film on a side of the curved surface.

5. The imaging device according to claim 1, wherein the seating includes, in the curved housing section, a ventilation section that penetrates from the curved surface toward a side of a back surface opposed to the curved surface.

6. The imaging device according to claim 1, comprising a mounting substrate to be mounted with the seating on a side of a back surface opposed to the curved surface, wherein
the seating includes an electric conductor having one end and another end, the one end being electrically coupled to the solid-state imaging element in the curved housing section, the other end being electrically coupled to the mounting substrate.

7. The imaging device according to claim 6, comprising a film disposed between the solid-state imaging element and the curved housing section, the film having an opening at a position corresponding to the electric conductor, the opening allowing for electrical coupling between the solid-state imaging element and the electric conductor.

8. The imaging device according to claim 7, comprising an element terminal disposed at a position corresponding to the opening of the film, on the back surface of the base opposed to the light-receiving surface of the solid-state imaging element, the element terminal allowing for electrical coupling between the solid-state imaging element and the electric conductor.

9. The imaging device according to claim 8, wherein the element terminal is protruded from a surface of the film on a side of the curved surface.

10. The imaging device according to claim 8, wherein
the electric conductor is protruded from the curved surface to a side of the film, and
the element terminal is recessed from a surface of the film on a side of the curved surface to a side of the solid-state imaging element.

11. The imaging device according to claim 8, wherein
the electric conductor is recessed from the curved surface to a side of the mounting substrate, and
the element terminal is protruded from a surface of the film on a side of the curved surface to the side of the curved surface.

12. The imaging device according to claim 8, wherein
the mounting substrate includes a mounting terminal at a position corresponding to the electric conductor, the mounting terminal being electrically coupled to the electric conductor,
the electric conductor is protruded from the back surface of the seating to a side of the mounting substrate, and
the mounting terminal is recessed from a surface of the mounting substrate on a side of the seating to a side of a back surface of the mounting substrate.

13. The imaging device according to claim 8, wherein
the mounting substrate includes a mounting terminal at a position corresponding to the electric conductor, the mounting terminal being electrically coupled to the electric conductor,
the electric conductor is recessed from the back surface of the seating to a side of the curved surface, and
the mounting terminal is protruded from a surface of the mounting substrate on a side of the seating to the side of the seating.

14. The imaging device according to claim 1, further comprising, between the solid-state imaging element and the curved housing section of the seating, a wiring substrate including a wiring layer and being formed in a curved shape along the curved surface of the curved housing section.

15. The imaging device according to claim 14, wherein
the wring substrate has flexibility,
a portion of the wiring substrate is extended to a periphery of a side surface of the seating, and
a portion of the wiring substrate is mounted with an electric element.

16. The imaging device according to claim 14, wherein the wiring substrate includes a plurality of the wiring layers.

17. A method of manufacturing an imaging device, the method comprising:
forming a solid-state imaging element including, on a base, a light-receiving surface on which a plurality of pixels is arranged in a two-dimensional array, the pixels each including a photoelectric conversion region that converts incident light into an electric signal;
forming a seating provided with a curved surface recessed in an incident direction of incident light, the seating including a curved housing section that houses the solid-state imaging element;
causing a back surface of the base opposed to the light-receiving surface and the curved surface to face each other; and
forming the solid-state imaging element in a curved state on the curved housing section, with a film being interposed between the solid-state imaging element and the curved housing section.
